(19) United States
(12) Patent Application Publication
(10) Pub. No.: US 2025/0133911 A1
(43) Pub. Date: Apr. 24, 2025

(54) DISPLAY DEVICE AND METHOD OF MANUFACTURING THE SAME

(71) Applicant: Samsung Display Co., LTD., Yongin-si (KR)

(72) Inventor: Chun Gi YOU, Yongin-si (KR)

(21) Appl. No.: 18/782,804

(22) Filed: Jul. 24, 2024

(30) Foreign Application Priority Data
Oct. 18, 2023 (KR) 10-2023-0139746

(51) Int. Cl. H10K 59/122; G02B 27/01; H10K 59/12; H10K 59/35; H10K 71/60

(52) U.S. Cl. CPC H10K 59/122; G02B 27/0172; H10K 59/1201; H10K 59/35; H10K 71/60

(57) ABSTRACT

A display device includes: a first electrode on a substrate; a pixel defining layer on the first electrode; a separation layer on the pixel defining layer and having a void and an opening partially exposing the void; a light emitting unit on the first electrode and the separation layer, the light emitting unit being separated at the opening in the separation layer; and a second electrode on the light emitting unit and covering the opening in the separation layer.

### CROSS-REFERENCE TO RELATED APPLICATION

The present application claims priority to and the benefit of Korean Patent Application No. 10-2023-0139746, filed Oct. 18, 2023, in the Korean Intellectual Property Office, the entire disclosure of which is incorporated herein by reference.

### BACKGROUND

### 1. Field

Aspects of embodiments of the present disclosure relate to a display device and a method of manufacturing the same.

### 2. Description of the Related Art

Recently, as interest in information display is increasing, research and development on display devices are continuously conducted.

### SUMMARY

Embodiments of the present disclosure provide a display device exhibiting improved reliability and a method of manufacturing the same.

Aspects and features of the present disclosure are not limited to those described above, and other aspects and features not mentioned will be clearly understood by those skilled in the art from the following description.

According to an embodiment of the present disclosure, a display device includes a first electrode on a substrate; a pixel defining layer on the first electrode; a separation layer on the pixel defining layer and having a void and an opening partially exposing the void; a light emitting unit on the first electrode and the separation layer and being separated at the opening in the separation layer; and a second electrode on the light emitting unit and covering the opening in the separation layer.

The display device may further include a conductive layer on the pixel defining layer.

The separation layer may at least partially surround the conductive layer.

The conductive layer may be in the void.

The separation layer may include an inorganic material.

The pixel defining layer may have a first area overlapping the void and a second area outside of the first area, and a thickness of the first area may be the same as a thickness of the second area.

The pixel defining layer may have a first area overlapping the void and a second area outside of the first area, and a thickness of the first area may be smaller than a thickness of the second area.

The substrate may include a first sub-pixel and a second sub-pixel adjacent to each other, and the separation layer may be at a boundary between the first sub-pixel and the second sub-pixel.

The light emitting unit of the first sub-pixel and the light emitting unit of the second sub-pixel may be separated at the opening in the separation layer.

The second electrode of the first sub-pixel and the second electrode of the second sub-pixel may be connected over the opening in the separation layer.

A method of manufacturing a display device, according to an embodiment of the present disclosure, includes: forming a first electrode on a substrate; forming a pixel defining layer on the first electrode; forming a metal layer on the pixel defining layer; forming a separation layer on the metal layer; forming an opening in the separation layer to at least partially expose the metal layer; etching the metal layer; and forming a light emitting unit on the first electrode and the separation layer.

During the etching of the metal layer, the metal layer may be removed to form a void between the pixel defining layer and the separation layer.

During the etching of the metal layer, the pixel defining layer may be partially etched.

The light emitting unit may be separated at the void.

The method of manufacturing a display device may further include forming a second electrode on the light emitting unit.

The second electrode may cover the opening in the separation layer.

The method of manufacturing a display device may further include forming a conductive layer on the pixel defining layer.

The metal layer may be formed directly on the conductive layer.

During the etching of the metal layer, the pixel defining layer may be covered by the conductive layer.

The separation layer may at least partially surround the conductive layer.

Additional aspects and features, and details and descriptions of other embodiments, are included in the detailed description and drawings.

### BRIEF DESCRIPTION OF THE DRAWINGS

The accompanying drawings are included to provide a further understanding of the present disclosure and are incorporated in and constitute a part of this specification. The drawings illustrate embodiments of the present disclosure, and, together with the description, describe aspects and features of the present disclosure.

FIG. 1 is a block diagram illustrating an embodiment of a display device.

FIG. 2 is a block diagram illustrating an embodiment of one sub-pixel of the display device shown in FIG. 1.

FIG. 3 is a circuit diagram illustrating an embodiment of the sub-pixel shown in FIG. 2.

FIG. 4 is a plan view illustrating an embodiment of a display panel shown in FIG. 1.

FIG. 5 is an exploded perspective view illustrating a portion of the display panel shown in FIG. 4.

FIG. 6 is a plan view illustrating an embodiment of one pixel of the display panel shown in FIG. 5.

FIG. 7 is a cross-sectional view taken along the line I-I′ in FIG. 6.

FIG. 8 is a cross-sectional view of a separation layer shown in FIG. 7.

FIG. 9 is a cross-sectional view taken along the line I-I′ in FIG. 6 according to another embodiment.

FIG. 10 is a cross-sectional view of a separation layer shown in FIG. 9.

FIG. 11 is a cross-sectional view of the separation layer shown in FIG. 9 according to another embodiment.

FIG. 12 is a cross-sectional view of a light emitting structure included in one from among first to third light emitting elements shown in FIG. 7.

FIG. 13 is a cross-sectional view of the light emitting structure included in one from among the first to third light emitting elements shown in FIG. 7 according to another embodiment.

FIG. 14 is a plan view of one of the pixels shown in FIG. 5 according to another embodiment.

FIG. 15 is a plan view of one of the pixels shown in FIG. 5 according to another embodiment.

FIG. 16 is a block diagram illustrating an embodiment of a display system.

FIG. 17 is a perspective view illustrating an application example of the display system shown in FIG. 16.

FIG. 18 is a diagram illustrating the head-mounted display device shown in FIG. 17 worn by a user.

FIGS. 19 to 29 are cross-sectional views illustrating process steps of a method of manufacturing a display device according to an embodiment.

FIGS. 30 to 38 are cross-sectional views illustrating process steps of a method of manufacturing a display device according to an embodiment.

### DETAILED DESCRIPTION

Hereinafter, embodiments of the present disclosure are described, in detail, with reference to the accompanying drawings. It should be noted that in the following description, portions necessary for understanding aspects and features of the present disclosure are described, and descriptions of other portions may be omitted in order not to obscure the subject matter of the present disclosure. In addition, the present disclosure may be embodied in other forms, and accordingly, is not limited to the embodiments described herein. However, the embodiments described herein are provided to describe, in detail, enough to easily implement the technical spirit of the present disclosure to those skilled in the art to which the disclosure belongs.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Various embodiments are described with reference to drawings schematically illustrating ideal embodiments. Accordingly, it will be expected that shapes may vary, for example, according to tolerances and/or manufacturing techniques. Therefore, the embodiments disclosed herein cannot be construed as being limited to shown specific shapes and should be interpreted as including, for example, changes in shapes that occur as a result of manufacturing. As described above, the shapes shown in the drawings may not show actual shapes of areas of a device, and the present embodiments are not limited thereto.

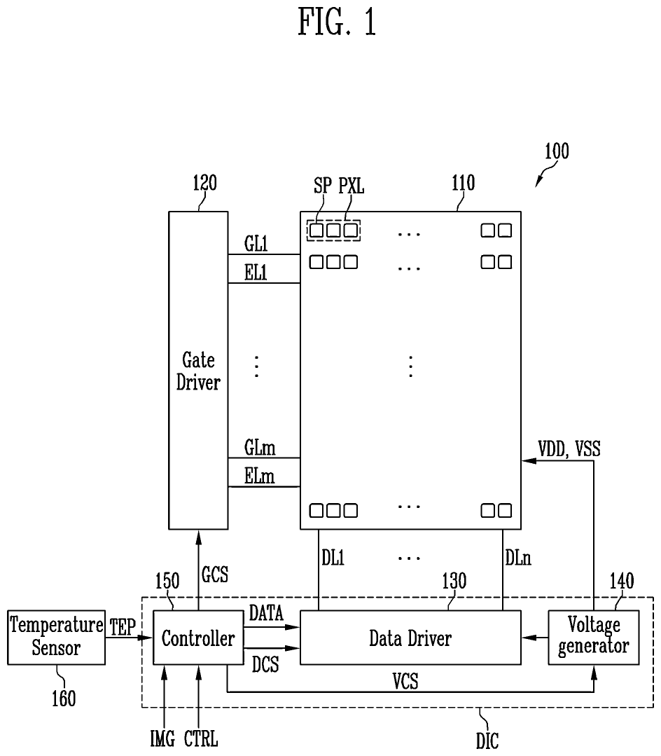

FIG. 1 is a block diagram illustrating an embodiment of a display device.

Referring to FIG. 1, a display device 100 may include a display panel 110, a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting element configured to generate light. Accordingly, each of the sub-pixels SP may generate light of a specific color, such as red, green, blue, cyan, magenta, yellow, or the like. Two or more sub-pixels from among the sub-pixels SP may constitute one pixel PXL. For example, in the embodiment shown in FIG. 1, three sub-pixels SP may constitute one pixel PXL.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In some embodiments, the gate control signal GCS may include a start signal indicating the start of each frame, a horizontal synchronization signal for outputting the gate signals in synchronization with the timing at which data signals are applied, and the like.

In some embodiments, first to m-th emission control lines EL1 to ELm connected to the sub-pixels SP and arranged in the row direction may be further provided. In such an embodiment, the gate driver 120 may include an emission control driver configured to control the first to m-th emission control lines EL1 to ELm, and the emission control driver may operate under the control of (e.g., may be controlled by) the controller 150.

The gate driver 120 may be disposed on one side of the display panel 110. However, embodiments are not limited thereto. For example, the gate driver 120 may be divided into two or more drivers physically and/or logically separated. Such drivers may be disposed on one side of the display panel 110 and on the other side of the display panel 110 opposite to the one side. As such, the gate driver 120 may be arranged around the display panel 110 in various shapes depending on embodiments.

The data driver 130 may be connected to the sub-pixels SP arranged in a column direction through the first to n-th data lines DL1 to DLn. The data driver 130 may receive image data DATA and a data control signal DCS from the controller 150. The data driver 130 may operate in response to the data control signal DCS. In some embodiments, the data control signal DCS may include a source start pulse, a source shift clock, a source output enable signal, and the like.

The data driver 130 may apply the data signals having grayscale voltages corresponding to the image data DATA to the first to n-th data lines DL1 to DLn by using voltages from the voltage generator 140. When a gate signal is applied to each of the first to m-th gate lines GL1 to GLm, the data signals corresponding to the image data DATA may be applied to the data lines DL1 to DLm. Accordingly, corresponding sub-pixels SP may generate light corresponding to the data signals. Accordingly, an image may be displayed on the display panel 110.

In some embodiments, the gate driver 120 and data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and may provide the generated voltages to components of the display device 100. For example, the voltage generator 140 may be configured to receive an input voltage from outside the display device 100, adjust the received voltage, and regulate the adjusted voltage to generate the plurality of voltages.

The voltage generator 140 may generate a first power source voltage VDD and a second power source voltage VSS, and the generated first and second power source voltages VDD and VSS may be provided to the sub-pixels SP. The first power source voltage VDD may have a relatively high voltage level, and the second power source voltage VSS may have a lower voltage level than the first power source voltage VDD. In other embodiments, the first power source voltage VDD or the second power source voltage VSS may be provided from a device external to the display device 100.

In addition, the voltage generator 140 may generate various voltages. For example, the voltage generator 140 may generate an initialization voltage applied to the sub-pixels SP. For example, during a sensing operation to sense the electrical characteristics of transistors and/or light emitting elements of the sub-pixels SP, a reference voltage (e.g., a predetermined reference voltage) may be applied to the first to n-th data lines DL1 to DLn, and the voltage generator 140 may generate the reference voltage.

The controller 150 may control various operations of the display device 100. The controller 150 may receive input image data IMG and a control signal CTRL for controlling the display of the input image data IMG from the outside. The controller 150 may provide the gate control signal GCS, the data control signal DCS, and the voltage control signal VCS in response to the control signal CTRL.

The controller 150 may convert the input image data IMG to suit the display device 100 or the display panel 110 to output the image data DATA. In some embodiments, the controller 150 may align the input image data IMG to suit the sub-pixels SP in row units to output the image data DATA.

Two or more components of the data driver 130, the voltage generator 140, and the controller 150 may be mounted on a single integrated circuit. As shown in FIG. 1, the data driver 130, the voltage generator 140, and the controller 150 may be included in a driver integrated circuit DIC. In such an embodiment, the data driver 130, the voltage generator 140, and the controller 150 may be components functionally separated within a single driver integrated circuit DIC. In other embodiments, at least one of the data driver 130, the voltage generator 140, and the controller 150 may be provided as another component separate from the driver integrated circuit DIC.

The display device 100 may include at least one temperature sensor 160. The temperature sensor 160 may be configured to sense the temperature of its surroundings and generate temperature data TEP representative of the sensed temperature. In some embodiments, the temperature sensor 160 may be disposed adjacent to the display panel 110 and/or the driver integrated circuit DIC.

The controller 150 may control various operations of the display device 100 in response to the temperature data TEP. In some embodiments, the controller 150 may adjust the luminance of the image output from the display panel 110 in response to the temperature data TEP. For example, the controller 150 may control the data signals and the first and second power source voltages VDD and VSS by controlling components, such as the data driver 130 and/or the voltage generator 140.

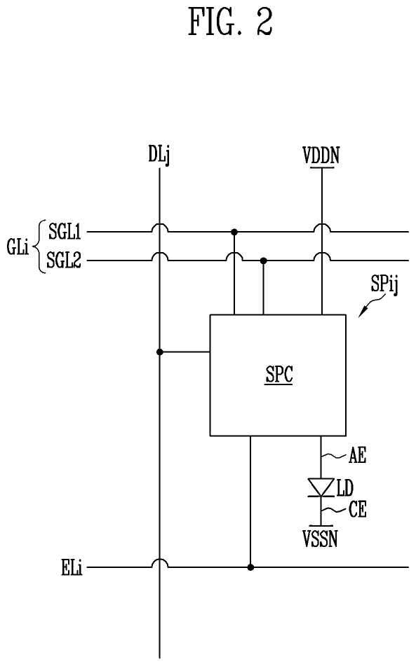

FIG. 2 is a block diagram illustrating an embodiment of one of the sub-pixels in the display panel 110 shown in FIG. 1. In FIG. 2, a sub-pixel SPij arranged in an i-th row and a j-th column from among the sub-pixels SP shown in FIG. 1 is shown as an example, where i may be an integer greater than or equal to 1 and less than or equal to m, and j may be an integer greater than or equal to 1 and less than or equal to n.

Referring to FIG. 2, the sub-pixel SPij may include a sub-pixel circuit SPC and a light emitting element LD.

The light emitting element LD may be connected between a first power source voltage node VDDN and a second power source voltage node VSSN. The first power source voltage node VDDN may be a node that transmits the first power source voltage VDD, and the second power source voltage node VSSN may be a node that transmits the second power source voltage VSS.

An anode electrode AE of the light emitting element LD may be connected to the first power source voltage node VDDN through the sub-pixel circuit SPC, and a cathode electrode CE of the light emitting element LD may be connected to the second power source voltage node VSSN. For example, the anode electrode AE of the light emitting element LD may be connected to the first power source voltage node VDDN through one or more transistors included in the sub-pixel circuit SPC.

The sub-pixel circuit PC may be connected to an i-th gate line GLi from among the first to m-th gate lines GL1 to GLm shown in FIG. 1, an i-th emission control line Eli from among the first to m-th emission control lines EL1 to ELm shown in FIG. 1, and a j-th data line DLj from among the first to n-th data lines DL1 to DLn shown in FIG. 1. The sub-pixel circuit SPC may be configured to control the light emitting element LD according to signals received through these signal lines.

The sub-pixel circuit SPC may operate in response to the gate signal received through the i-th gate line GLi. The i-th gate line GLi may include one or more sub-gate lines. In some embodiments, as shown in, for example, FIG. 2, the i-th gate line GLi may include first and second sub-gate lines SGL1 and SGL2. The sub-pixel circuit SPC may operate in response to gate signals received through the first and second sub-gate lines SGL1 and SGL2. As such, when the i-th gate line GLi includes two or more sub-gate lines, the sub-pixel circuit SPC may operate in response to gate signals received through corresponding sub-gate lines.

The sub-pixel circuit SPC may operate in response to an emission control signal received through the i-th emission control line ELi. In some embodiments, the i-th emission control line ELi may include one or more sub-emission control lines. When the i-th emission control line ELi includes two or more sub-emission control lines, the sub-pixel circuit SPC may operate in response to emission control signals received through corresponding sub-emission control lines.

The sub-pixel circuit SPC may receive a data signal through the j-th data line DLj. The sub-pixel circuit SPC may store a voltage corresponding to the data signal in response to at least one of the gate signals received through the first and second sub-gate lines SGL1 and SGL2. The sub-pixel circuit SPC may adjust current flowing from the first power source voltage node VDDN to the second power source voltage node VSSN through the light emitting element LD according to the stored voltage in response to the emission control signal received through the i-th emission control line Eli. Accordingly, the light emitting element LD may generate light with a luminance corresponding to the data signal.

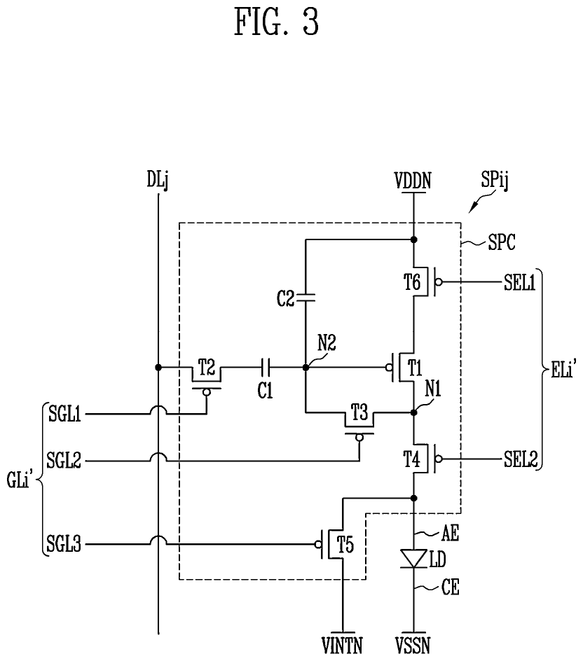

FIG. 3 is a circuit diagram illustrating an embodiment of the sub-pixel shown in FIG. 2.

Referring to FIG. 3, the sub-pixel SPij may include a sub-pixel circuit SPC and a light emitting element LD.

The sub-pixel circuit SPC may be connected to an i-th gate line GLi′, an i-th emission control line ELi′, and a j-th data line DLj. Compared to the i-th gate line GLi shown in FIG. 2, the i-th gate line GLi′ may further include a third sub-gate line SGL3. Compared to the i-th emission control line ELi shown in FIG. 2, the i-th emission control line ELi′ may include a first sub-emission control line SEL1 and a second sub-emission control line SEL2.

The sub-pixel circuit SPC may include first to sixth transistors T1 to T6 and first and second capacitors C1 and C2.

The first transistor T1 may be connected between the first power source voltage node VDDN and a first node N1. A gate of the first transistor T1 may be connected to a second node N2. Accordingly, the first transistor T1 may be turned on according to a voltage level of the second node N2. The first transistor T1 may be referred to as a driving transistor.

The second transistor T2 may be connected between the j-th data line DLj and the second node N2. A gate of the second transistor T2 may be connected to the first sub-gate line SGL1. Accordingly, the second transistor T2 may be turned on in response to the gate signal of the first sub-gate line SGL1. The second transistor T2 may be referred to as a switching transistor.

The third transistor T3 may be connected between the first node N1 and the second node N2. A gate of the third transistor T3 may be connected to the second sub-gate line SGL2. Accordingly, the third transistor T3 may be turned on in response to the gate signal of the second sub-gate line SGL2.

The fourth transistor T4 may be connected between the first node N1 and the anode electrode AE of the light emitting element LD. A gate of the fourth transistor T4 may be connected to the second sub-emission control line SEL2. Accordingly, the fourth transistor T4 may be turned on in response to the emission control signal of the second sub-emission control line SEL2.

The fifth transistor T5 may be connected between the anode electrode AE of the light emitting element LD and an initialization voltage node VINTN. The initialization voltage node VINTN may be configured to transmit the initialization voltage. In some embodiments, the initialization voltage may be provided from the voltage generator 140 shown in, for example, FIG. 1. In other embodiments, the initialization voltage may be provided from a device external to the display device 100. A gate of the fifth transistor T5 may be connected to the third sub-gate line SGL3. Accordingly, the fifth transistor T5 may be turned on in response to the gate signal of the third sub-gate line SGL3.

The sixth transistor T6 may be connected between the first power source voltage node VDDN and the first transistor T1. A gate of the sixth transistor T6 may be connected to the first sub-emission control line SEL1. Accordingly, the sixth transistor T6 may be turned on in response to the emission control signal of the first sub-emission control line SEL1.

The first capacitor C1 may be connected between the second transistor T2 and the second node N2. The second capacitor C2 may be connected between the first power source voltage node VDDN and the second node N2.

As such, the sub-pixel circuit SPC may include the first to sixth transistors T1 to T6 and the first and second capacitors C1 and C2. However, embodiments are not limited thereto. The sub-pixel circuit SPC may be implemented as one of various types of circuits including a plurality of transistors and one or more capacitors. For example, the sub-pixel circuit SPC may include two transistors and one capacitor. According to embodiments of the sub-pixel circuit SPC, the number of sub-gate lines included in the i-th gate line GLi′ and the number of sub-emission control lines included in the i-th emission control line ELi′ may be variable.

The first to sixth transistors T1 to T6 may be P-type transistors. Each of the first to sixth transistors T1 to T6 may be a MOSFET (Metal Oxide Silicon Field Effect Transistor). However, embodiments are not limited thereto. For example, at least one of the first to sixth transistors T1 to T6 may be an N-type transistor.

In some embodiments, the first to sixth transistors T1 to T6 may include an amorphous silicon semiconductor, a monocrystalline silicon semiconductor, a polycrystalline silicon semiconductor, an oxide semiconductor, or the like.

The light emitting element LD may include the anode electrode AE, the cathode electrode CE, and a light emitting layer. The light emitting layer may be disposed between the anode electrode AE and the cathode electrode CE. After the data signal transmitted through the j-th data line DLj is reflected in a voltage at the second node N2, the emission control signals of the first and second sub-emission control lines SEL1 and SEL2 are enabled at a low level, the fourth and sixth transistors T4 and T6 may be turned on. The first transistor T1 may be turned on according to the voltage at the second node N2. Accordingly, current may flow from the first power source voltage node VDDN to the second power source voltage node VSSN. The light emitting element LD may emit light depending on the amount of current flowing therethrough.

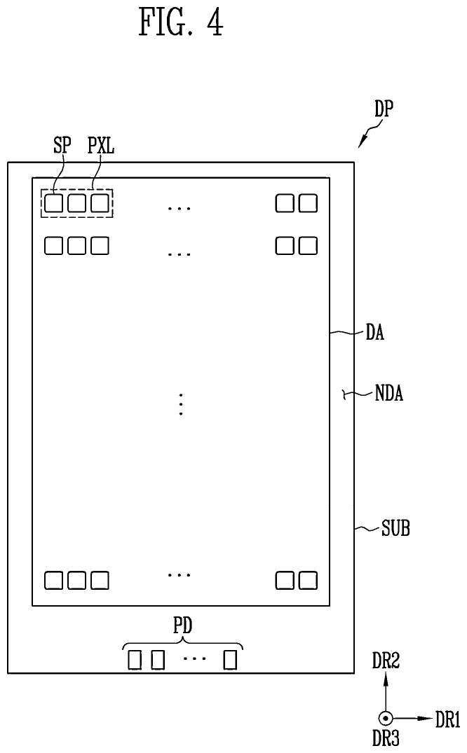

FIG. 4 is a plan view illustrating an embodiment of a display panel shown in FIG. 1.

Referring to FIG. 4, an embodiment DP of the display panel 110 shown in FIG. 1 may have a display area DA and a non-display area NDA. The display panel DP may display an image at the display area DA. The non-display area NDA may be disposed around the display area DA.

The display panel DP may include a substrate SUB, sub-pixels SP, and pads PD.

When the display panel DP is used as a display screen for a head-mounted display (HMD) device, a virtual reality (VR) device, a mixed reality (MR) device, an augmented reality (AR) device, or the like, the display panel DP may be positioned very close to the user's eyes. In such an embodiment, sub-pixels SP with relatively high integration may be required. To increase the integration of the sub-pixels SP, the substrate SUB may be provided as a silicon substrate. The sub-pixels SP and/or the display panel DP may be formed on the silicon substrate. The display device 100 (see, e.g., FIG. 1) including the display panel DP formed on the substrate SUB may be referred to as an OLED on Silicon (OLEDoS) display device.

The sub-pixels SP may be disposed in the display area DA on the substrate SUB. The sub-pixels SP may be arranged in a matrix form along a first direction DR1 and a second direction DR2 crossing the first direction DR1. However, embodiments are not limited thereto. For example, the sub-pixels SP may be arranged in a zigzag shape along the first direction DR1 and the second direction DR2. For example, the sub-pixels SP may be arranged in a PENTILE® shape (PENTILE® is a registered trademark of Samsung Display Co., Ltd), also referred to as a diamond pattern. The first direction DR1 may be a row direction, and the second direction DR2 may be a column direction.

Two or more sub-pixels from among a plurality of sub-pixels SP may constitute one pixel PXL.

Components for controlling the sub-pixels SP may be disposed in the non-display area NDA on the substrate SUB. For example, wirings connected to the sub-pixels SP, such as the first to m-th gate lines GL1 to GLm and the first to n-th data lines DL1 to DLn shown in FIG. 1, may be disposed in the non-display area NDA.

At least one of the gate driver 120, the data driver 130, the voltage generator 140, the controller 150, and the temperature sensor 160 shown in FIG. 1 may be integrated in the non-display area NDA of the display panel DP. In some embodiments, the gate driver 120 shown in FIG. 1 may be mounted on the display panel DP and disposed in the non-display area NDA. In other embodiments, the gate driver 120 may be implemented as an integrated circuit separate from the display panel DP. In some embodiments, the temperature sensor 160 may be disposed in the non-display area NDA to detect the temperature of the display panel DP.

The pads PD may be disposed in the non-display area NDA on the substrate SUB. The pads PD may be electrically connected to the sub-pixels SP through the wirings. For example, the pads PD may be connected to the sub-pixels SP through the first to n-th data lines DL1 to DLn.

The pads PD may interface the display panel DP to other components of the display device 100 (see, e.g., FIG. 1). In some embodiments, voltages and signals necessary for the operation of components included in the display panel DP may be provided through the pads PD from the driver integrated circuit DIC shown in FIG. 1. For example, the first to n-th data lines DL1 to DLn may be connected to the driver integrated circuit DIC through the pads PD. For example, the first and second power source voltages VDD and VSS may be received from the driver integrated circuit DIC through the pads PD. For example, when the gate driver 120 is mounted on the display panel DP, the gate control signal GCS may be transmitted from the driver integrated circuit DIC to the gate driver 120 through the pads PD.

In some embodiments, a circuit board may be electrically connected to the pads PD by using a conductive adhesive member, such as an anisotropic conductive film. In such an embodiment, the circuit board may be a flexible circuit board (FPCB) or a flexible film made of a flexible material. The driver integrated circuit DIC may be mounted on the circuit board and electrically connected to the pads PD.

In some embodiments, the display area DA may have various shapes. The display area DA may have a closed loop shape with straight and/or curved sides. For example, the display area DA may have a shape, such as a polygon, circle, semicircle, or ellipse.

In some embodiments, the display panel DP may have a flat display surface. In other embodiments, the display panel DP may have a display surface that is at least partially rounded. In some embodiments, the display panel DP may be bent, folded, or rolled. In these embodiments, the display panel DP and/or the substrate SUB may include materials with flexible properties.

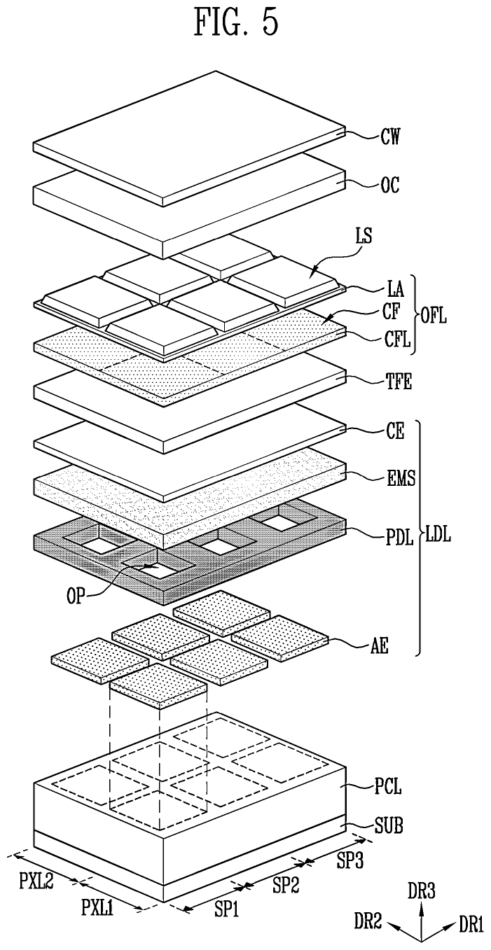

FIG. 5 is an exploded perspective view illustrating a portion of the display panel shown in FIG. 4. In FIG. 5, for clear and concise explanation, portions of the display panel DP corresponding to two pixels PXL1 and PXL2 from among the pixels PXL shown in FIG. 4 are schematically shown. Portions of the display panel DP corresponding to the remaining pixels may be similarly configured.

Referring to FIGS. 4 and 5, each of first and second pixels PXL1 and PXL2 may include first to third sub-pixels SP1, SP2, and SP3. However, embodiments are not limited thereto. For example, each of the first and second pixels PXL1 and PXL2 may include four sub-pixels or two sub-pixels.

FIG. 5 shows an embodiment in which the first to third sub-pixels SP1, SP2, and SP3 have a square shape and a same size when viewed in a third direction DR3 crossing the first and second directions DR1 and DR2. However, embodiments are not limited thereto. The first to third sub-pixels SP1, SP2, and SP3 may have various shapes.

The display panel DP may include the substrate SUB, a pixel circuit layer PCL, a light emitting element layer LDL, an encapsulation layer TFE, an optical functional layer OFL, an overcoat layer OC, and a cover window CW.

In some embodiments, the substrate SUB may include a silicon wafer substrate formed through a semiconductor process. The substrate SUB may include a semiconductor material suitable for forming circuit elements. For example, the semiconductor material may include silicon, germanium, and/or silicon-germanium. The substrate SUB may also be provided from a bulk wafer, an epitaxial layer, a silicon on insulator (SOI) layer, a semiconductor on insulator (SeOI) layer, or the like. In other embodiments, the substrate SUB may include a glass substrate. In other embodiments, the substrate SUB may include a polyimide (PI) substrate.

The pixel circuit layer PCL may be disposed on the substrate SUB. The substrate SUB and/or the pixel circuit layer PCL may include insulating layers and conductive patterns disposed between the insulating layers. The conductive patterns of the pixel circuit layer PCL may act as at least part of circuit elements, wirings, and the like. The conductive patterns may include copper, but embodiments are not limited thereto.

The circuit elements may include the sub-pixel circuit SPC (see, e.g., FIG. 2) of each of the first to third sub-pixels SP1, SP2, and SP3. The sub-pixel circuit SPC may include transistors and one or more capacitors. Each transistor may include a semiconductor portion having a source region, a drain region, and a channel region, and a gate electrode overlapping the semiconductor portion. In some embodiments, when the substrate SUB is provided as a silicon substrate, the semiconductor portion may be included within the substrate SUB, and the gate electrode may be included within the pixel circuit layer PCL as a conductive pattern of the pixel circuit layer PCL. In some embodiments, when the substrate SUB is provided as a glass substrate or a PI substrate, the semiconductor portion and the gate electrode may be included within the pixel circuit layer PCL. Each capacitor may include electrodes spaced apart from each other. For example, each capacitor may include electrodes spaced apart from each other on a plane defined by the first and second directions DR1 and DR2. For example, each capacitor may include electrodes spaced apart from each other in the third direction DR3 with an insulating layer interposed therebetween.

The wirings of the pixel circuit layer PCL may include signal lines connected to each of the first to third sub-pixels SP1, SP2, and SP3, for example, a gate line, an emission control line, a data line, and the like. The wirings may further include a wiring connected to the first power source voltage node VDDN shown in FIG. 2. The wirings may further include a wiring connected to the second power source voltage node VSSN shown in FIG. 2.

The light emitting element layer LDL may include anode electrodes AE, a pixel defining layer PDL, a light emitting structure EMS, and a cathode electrode CE.

The anode electrodes AE may be disposed on the pixel circuit layer PCL. The anode electrodes AE may be in contact with the circuit elements of the pixel circuit layer PCL. The anode electrodes AE may include an opaque conductive material capable of reflecting light, but embodiments are not limited thereto.

The pixel defining layer PDL may be disposed on the anode electrodes AE. The pixel defining layer PDL may have openings OP exposing portions of the anode electrodes AE. The openings OP in the pixel defining layer PDL may be understood as emission areas corresponding to the first to third sub-pixels SP1 to SP3.

In some embodiments, the pixel defining layer PDL may include an inorganic material. In such an embodiment, the pixel defining layer PDL may include a plurality of stacked inorganic layers. For example, the pixel defining layer PDL may include silicon oxide (SiOₓ) and silicon nitride (SiNₓ). In other embodiments, the pixel defining layer PDL may include an organic material. However, the material of the pixel defining layer PDL is not limited thereto.

The light emitting structure EMS may be disposed on the anode electrodes AE exposed by the openings OP in the pixel defining layer PDL. The light emitting structure EMS may include a light emitting layer configured to generate light, an electron transport layer configured to transport electrons, a hole transport layer configured to transport holes, and the like.

In some embodiments, the light emitting structure EMS may fill the openings OP in the pixel defining layer PDL and may be entirely disposed on an upper surface of the pixel defining layer PDL. The light emitting structure EMS may extend across the first to third sub-pixels SP1 to SP3. In such an embodiment, at least some of layers in the light emitting structure EMS may be separated (e.g., broken) or bent at boundaries between the first to third sub-pixels SP1 to SP3. However, embodiments are not limited thereto. For example, portions of the light emitting structure EMS corresponding to the first to third sub-pixels SP1 to SP3 may be separated from each other, and separated light emitting structures EMS may be disposed within the openings OP in the pixel defining layer PDL.

The cathode electrode CE may be disposed on the light emitting structure EMS. The cathode electrode CE may extend across the first to third sub-pixels SP1 to SP3. Accordingly, the cathode electrode CE may act as a common electrode for the first to third sub-pixels SP1 to SP3.

The cathode electrode CE may be a thin metal layer having a thickness sufficient to transmit light emitted from the light emitting structure EMS. The cathode electrode CE may be formed of a metal material or a transparent conductive material to have a relatively thin thickness. In some embodiments, the cathode electrode CE may include at least one of various transparent conductive materials, such as indium tin oxide, indium zinc oxide, indium tin zinc oxide, aluminum zinc oxide, gallium zinc oxide, zinc tin oxide, and gallium tin oxide. In other embodiments, the cathode electrode CE may include at least one of silver (Ag), magnesium (Mg), and mixtures thereof. However, the material of the cathode electrode CE is not limited thereto.

One of the anode electrodes AE, a portion of the light emitting structure EMS overlapping therewith, and a portion of the cathode electrode CE overlapping therewith may be understood as constituting one light emitting element LD (see, e.g., FIG. 2). Each of light emitting elements of the first to third sub-pixels SP1 to SP3 may include one anode electrode AE, a portion of the light emitting structure EMS overlapping therewith, and a portion of the cathode electrode CE overlapping therewith. In each of the first to third sub-pixels SP1 to SP3, holes injected from the anode electrode AE and electrons injected from the cathode electrode CE may be transported into the light emitting layer of the light emitting structure EMS to generate excitons. When the excitons transition from an excited state to a ground state, light may be generated. The luminance of the light may be determined depending on the amount of current flowing through the light emitting layer. Depending on the configuration of the light emitting layer, the wavelength range of the generated light may be determined.

The encapsulation layer TFE may be disposed on the cathode electrode CE. The encapsulation layer TFE may cover the light emitting element layer LDL and/or the pixel circuit layer PCL. The encapsulation layer TFE may be configured to prevent oxygen and/or moisture from penetrating into the light emitting element layer LDL. In some embodiments, the encapsulation layer TFE may include a structure in which one or more inorganic layers and one or more organic layers are alternately stacked on each other. For example, the inorganic layer may include silicon nitride, silicon oxide, silicon oxynitride (SiOₓN_{y}), or the like. For example, the organic layer may include an organic insulating material, such as an acrylic resin, an epoxy resin, a phenol resin, a polyamide resin, a polyimide resin, an unsaturated polyester resin, a polyphenylene ether resin, a polyphenylene sulfide resin, benzocyclobutene (BCB), or the like. However, the materials of the organic and inorganic layers constituting the encapsulation layer TFE are not limited thereto.

To improve encapsulation efficiency of the encapsulation layer TFE, the encapsulation layer TFE may further include a thin film including aluminum oxide (AlOₓ). The thin film including aluminum oxide may be located on an upper surface of the encapsulation layer TFE facing the optical functional layer OFL and/or on a lower surface of the encapsulating layer TFE facing the light emitting element layer LDL.

The thin film including aluminum oxide may be formed through an atomic layer deposition (ALD) method. However, embodiments are not limited thereto. The encapsulation layer TFE may further include a thin film formed of at least one of various materials suitable for improving the encapsulation efficiency.

The optical functional layer OFL may be disposed on the encapsulation layer TFE. The optical functional layer OFL may include a color filter layer CFL and a lens array LA.

The color filter layer CFL may be disposed between the encapsulation layer TFE and the lens array LA. The color filter layer CFL may be configured to filter the light emitted from the light emitting structure EMS to selectively output light in a wavelength range or color corresponding to each sub-pixel. The color filter layer CFL may include color filters CF corresponding to the first to third sub-pixels SP1 to SP3. Each of the color filters CF may transmit light in a wavelength range corresponding to each sub-pixel. For example, a color filter corresponding to the first sub-pixel SP1 may transmit red light, a color filter corresponding to the second sub-pixel SP2 may transmit green light, and a color filter corresponding to the third sub-pixel SP3 may transmit blue light. Depending on the light emitted from the light emitting structure EMS of each sub-pixel, at least some of the color filters CF may be omitted.

The lens array LA may be disposed on the color filter layer CFL. The lens array LA may include lenses LS corresponding to the first to third sub-pixels SP1 to SP3. Each of the lenses LS may improve light output efficiency by outputting the light emitted from the light emitting structure EMS along an intended path. The lens array LA may have a relatively high refractive index. For example, the lens array LA may have a higher refractive index than the overcoat layer OC. In some embodiments, the lenses LS may include an organic material. In some embodiments, the lenses LS may include an acrylic material. However, the material of the lenses LS is not limited thereto.

In some embodiments, compared to the openings OP in the pixel defining layer PDL, at least some of the color filters CF of the color filter layer CFL and at least some of the lenses LS of the lens array LA may be shifted in a direction parallel to a plane defined by the first and second directions DR1 and DR2. For example, in the central area of the display area DA, the center of a color filter and the center of a lens may be aligned or overlap with the center of an opening OP in the pixel defining layer PDL when viewed in the third direction DR3. For example, in the central area of the display area DA, the openings OP in the pixel defining layer PDL may completely overlap the corresponding color filter of the color filter layer CFL and the corresponding lens of the lens array LA. In an area of the display area DA adjacent to the non-display area NDA, the center of the color filter and the center of the lens may be shifted in a plane direction from the center of the opening OP in the pixel defining layer PDL when viewed in the third direction DR3. For example, in an area of the display area DA adjacent to the non-display area NDA, the opening OP in the pixel defining layer PDL may partially overlap the corresponding color filter of the color filter layer CFL and the corresponding lens of the lens array LA. Accordingly, in the central area of the display area DA, the light emitted from the light emitting structure EMS may be efficiently output in a normal direction of the display surface. In a peripheral area of the display area DA, the light emitted from the light emitting structure EMS may be efficiently output in a direction inclined by an angle (e.g., a predetermined angle) with respect to the normal direction of the display surface.

The overcoat layer OC may be disposed on the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting lower layers from foreign substances, such as dust, moisture, and the like. For example, the overcoat layer OC may include at least one of an inorganic insulating layer and an organic insulating layer. For example, the overcoat layer OC may include epoxy, but embodiments are not limited thereto. The overcoat layer OC may have a lower refractive index than the lens array LA.

The cover window CW may be disposed on the overcoat layer OC. The cover window CW may be configured to protect lower layers. The cover window CW may have a higher refractive index than the overcoat layer OC. The cover window CW may include glass, but embodiments are not limited thereto. For example, the cover window CW may be an encapsulation glass configured to protect components disposed below. In other embodiments, the cover window CW may be omitted.

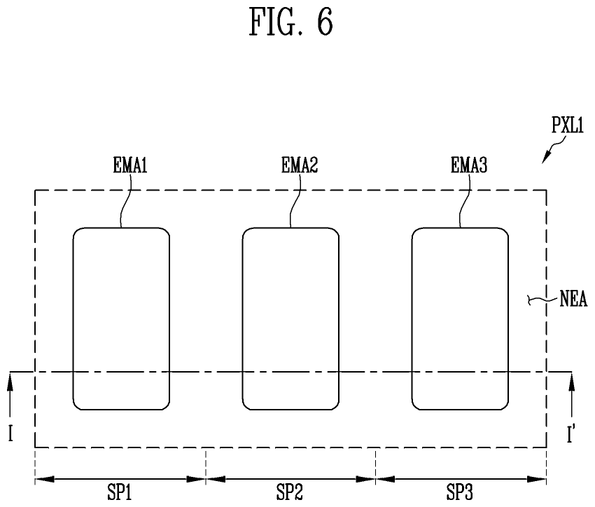

FIG. 6 is a plan view illustrating an embodiment of one of the pixels shown in FIG. 5. FIG. 6 schematically shows the first pixel PXL1 from among the first and second pixels PXL1 and PXL2 shown in FIG. 5 for clear and concise explanation. The remaining pixels may be similarly configured to the first pixel PXL1.

Referring to FIGS. 5 and 6, the first pixel PXL1 may include first to third sub-pixels SP1 to SP3 arranged in the first direction DR1.

The first sub-pixel SP1 may have a first emission area EMA1 and a non-emission area NEA around the first emission area EMA1. The second sub-pixel SP2 may include a second emission area EMA2 and a non-emission area NEA around the second emission area EMA2. The third sub-pixel SP3 may include a third emission area EMA3 and a non-emission area NEA around the third emission area EMA3.

The first emission area EMA1 may be an area where light is emitted from a portion of the light emitting structure EMS (see, e.g., FIG. 5) corresponding to the first sub-pixel SP1. The second emission area EMA2 may be an area where light is emitted from a portion of the light emitting structure EMS corresponding to the second sub-pixel SP2. The third emission area EMA3 may be an area where light is emitted from a portion of the light emitting structure EMS corresponding to the third sub-pixel SP3. As described with reference to FIG. 5, each emission area may be understood as the opening OP in the pixel defining layer PDL corresponding to each of the first to third sub-pixels SP1 to SP3.

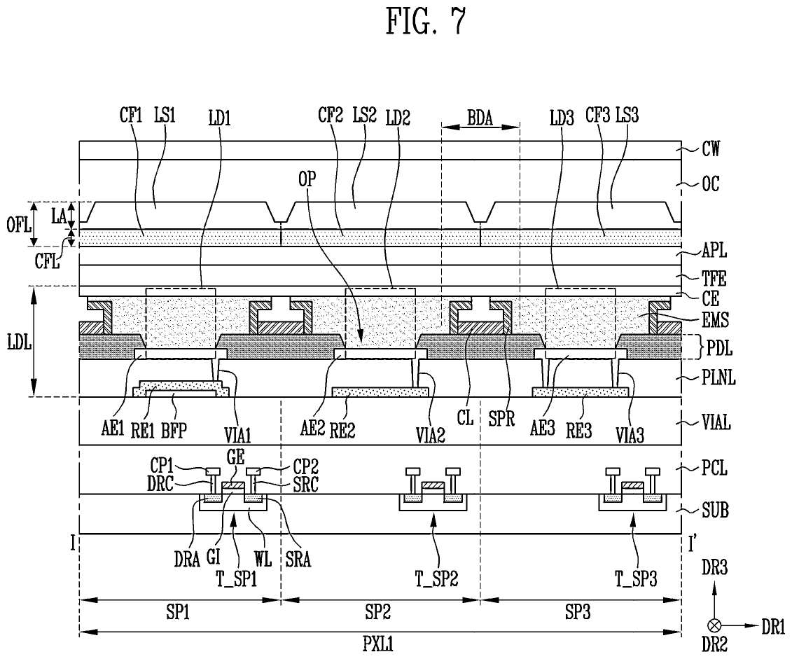

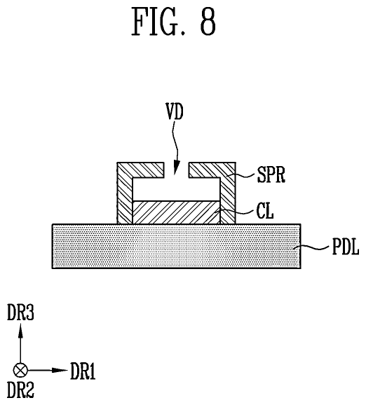

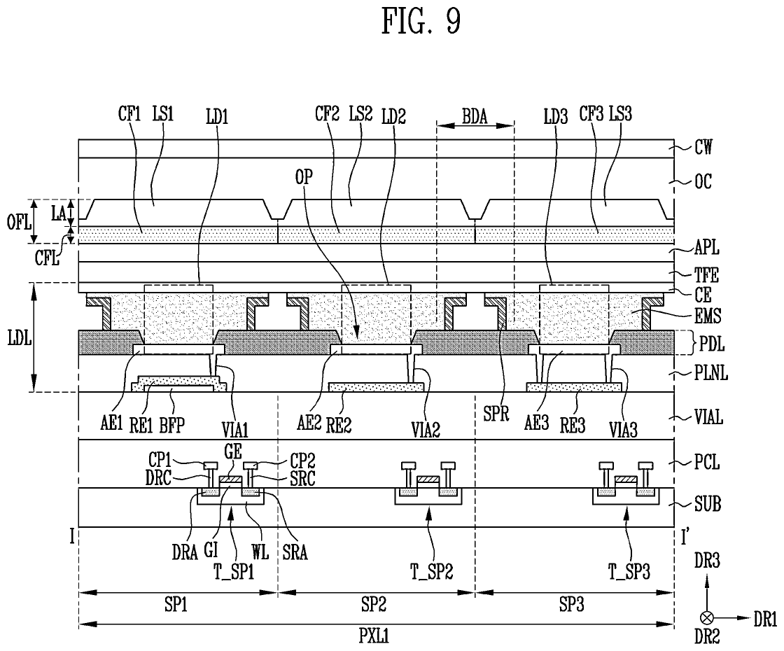

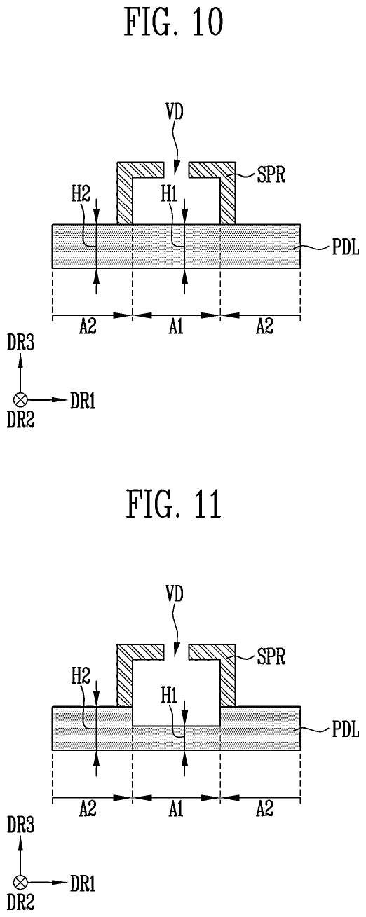

FIG. 7 is a cross-sectional view taken along the line I-I′ in FIG. 6. FIG. 8 is a cross-sectional view of a separation layer shown in FIG. 7. FIG. 9 is a cross-sectional view taken along the line I-I′ in FIG. 6 according to another embodiment. FIG. 10 is a cross-sectional view of a separation layer shown in FIG. 9. FIG. 11 is a cross-sectional view of the separation layer shown in FIG. 9 according to another embodiment.

Referring to FIG. 7, the substrate SUB and the pixel circuit layer PCL disposed on the substrate SUB may be provided.

The substrate SUB may include a silicon wafer substrate formed through a semiconductor process. For example, the substrate SUB may include silicon, germanium, and/or silicon-germanium.

The pixel circuit layer PCL may be disposed on the substrate SUB. The substrate SUB and the pixel circuit layer PCL may include circuit elements of each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of the transistors included in the sub-pixel circuit SPC (see, e.g., FIG. 2) of the first sub-pixel SP1. The transistor T_SP2 of the second sub-pixel SP2 may be one of the transistors included in the sub-pixel circuit SPC of the second sub-pixel SP2. The transistor T_SP3 of the third sub-pixel SP3 may be one of the transistors included in the sub-pixel circuit SPC of the third sub-pixel SP3. In FIG. 7, for clear and concise explanation, one of the transistors of each sub-pixel is shown, and the remaining circuit elements are omitted.

The transistor T_SP1 of the first sub-pixel SP1 may include a source region SRA, a drain region DRA, and a gate electrode GE.

The source region SRA and the drain region DRA may be disposed within the substrate SUB. A well WL formed through an ion implantation process may be disposed within the substrate SUB, and the source region SRA and the drain region DRA may be disposed to be spaced apart from each other within the well WL. A region between the source region SRA and the drain region DRA within the well WL may be defined as a channel region.

The gate electrode GE may overlap the channel region between the source region SRA and the drain region DRA and may be disposed in the pixel circuit layer PCL. The gate electrode GE may be spaced apart from the well WL or the channel region by an insulating material, such as a gate insulating layer GI. The gate electrode GE may include a conductive material.

A plurality of layers included in the pixel circuit layer PCL may include insulating layers and conductive patterns disposed between the insulating layers. The conductive patterns may include first and second conductive patterns CP1 and CP2. The first conductive pattern CP1 may be electrically connected to the drain region DRA through a drain connection portion DRC penetrating (or extending through) one or more insulating layers. The second conductive pattern CP2 may be electrically connected to the source region SRA through a source connection portion SRC penetrating (or extending through) one or more insulating layers.

Because the gate electrode GE and the first and second conductive patterns CP1 and CP2 are connected to other circuit elements and/or wirings, the transistor T_SP1 of the first sub-pixel SP1 may be provided as one of the transistors of the first sub-pixel SP1.

Each of the transistor T_SP2 of the second sub-pixel SP2 and the transistor T_SP3 of the third sub-pixel SP3 may be similarly configured as the transistor T_SP1 of the first sub-pixel SP1.

As such, the substrate SUB and the pixel circuit layer PCL may include circuit elements of each of the first to third sub-pixels SP1 to SP3.

A via layer VIAL may be disposed on the pixel circuit layer PCL. The via layer VIAL may cover the pixel circuit layer PCL and may have an overall flat surface. The via layer VIAL may be configured to flatten step differences of the pixel circuit layer PCL. The via layer VIAL may include at least one of silicon oxide (SiOₓ), silicon nitride (SiNₓ), and silicon carbon nitride (SiCN), but embodiments are not limited thereto.

The light emitting element layer LDL may be disposed on the via layer VIAL. The light emitting element layer LDL may include first to third reflective electrodes RE1 to RE3, a planarization layer PLNL, first to third anode electrodes AE1 to AE3, a pixel defining layer PDL, a light emitting structure EMS, and a cathode electrode CE.

On the via layer VIAL, the first to third reflective electrodes RE1 to RE3 may be disposed in the first to third sub-pixels SP1 to SP3, respectively. Each of the first to third reflective electrodes RE1 to RE3 may contact a circuit element disposed in the pixel circuit layer PCL through a via penetrating (or extending through) the via layer VIAL.

The first to third reflective electrodes RE1 to RE3 may act as mirrors (e.g., full mirrors) that reflect the light emitted from the light emitting structure EMS toward the display surface (or the cover window CW). The first to third reflective electrodes RE1 to RE3 may include metal materials suitable for reflecting light. The first to third reflective electrodes RE1 to RE3 may include at least on of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected from these, but embodiments are not limited thereto.

In some embodiments, a connection electrode may be disposed below each of the first to third reflective electrodes RE1 to RE3. The connection electrode may improve electrical connection characteristics between a corresponding reflective electrode and a circuit element of the pixel circuit layer PCL. The connection electrode may have a multilayer structure. The multilayer structure may include titanium (Ti), titanium nitride (TiN), tantalum nitride (TaN), or the like, but embodiments are not limited thereto. In some embodiments, the corresponding reflective electrode may be positioned between multiple layers of the connection electrode.

A buffer pattern BFP may be disposed below at least one of the first to third reflective electrodes RE1 to RE3. The buffer pattern BFP may include an inorganic material, such as silicon carbon nitride, but embodiments are not limited thereto. By disposing the buffer pattern BFP, the height of the corresponding reflective electrode in the third direction DR3 can be adjusted. For example, the buffer pattern BFP may be disposed between the first reflective electrode RE1 and the via layer VIAL to adjust the height of the first reflective electrode RE1.

The first to third reflective electrodes RE1 to RE3 may act as mirrors (e.g., full mirrors), and the cathode electrode CE may act as a half mirror. Light emitted from the light emitting layer of the light emitting structure EMS may be amplified by at least partially reciprocating between the corresponding reflective electrode and the cathode electrode CE. The amplified light may be output through the cathode electrode CE. As described above, the distance between each reflective electrode and the cathode electrode CE may be understood as a resonance distance for the light emitted from the light emitting layer of the corresponding light emitting structure EMS.

The first sub-pixel SP1 may have a shorter resonance distance than other sub-pixels due to the buffer pattern BFP. The resonance distance adjusted in this way may effectively and efficiently amplify light in a specific wavelength range (for example, red). Accordingly, the first sub-pixel SP1 may effectively and efficiently output light in a corresponding wavelength range.

FIG. 7 shows an embodiment in which the buffer pattern BFP is provided only in the first sub-pixel SP1 but not in the second and third sub-pixels SP2 and SP3. However, embodiments are not limited thereto. The buffer pattern is provided to at least one of the second and third sub-pixels SP2 and SP3 so that the resonance distance of at least one of the second and third sub-pixels SP2 and SP3 can be adjusted. For example, the first to third sub-pixels SP1 to SP3 may correspond to red, green, and blue, respectively. In addition, the distance between the first reflection electrode RE1 and the cathode electrode CE may be shorter than the distance between the second reflection electrode RE2 and the cathode electrode CE, and the distance between the second reflective electrode RE2 and the cathode electrode CE may be shorter than the distance between the third reflective electrode RE3 and the cathode electrode CE.

To flatten step differences between the first to third reflective electrodes RE1 to RE3, a planarization layer PLNL may be disposed on the via layer VIAL and the first to third reflective electrodes RE1 to RE3. The planarization layer PLNL may generally cover the first to third reflective electrodes RE1 to RE3 and the via layer VIAL and may have a flat surface. In some embodiments, the planarization layer PLNL may be omitted.

The first to third anode electrodes AE1 to AE3 may be disposed on the planarization layer PLNL to overlap the first to third reflection electrodes RE1 to RE3. The first to third anode electrodes AE1 to AE3 may have shapes similar to the first to third emission areas EMA1 to EMA3 shown in FIG. 6 when viewed in the third direction DR3. The first to third anode electrodes AE1 to AE3 may be connected to the first to third reflective electrodes RE1 to RE3, respectively. The first anode electrode AE1 may be connected to the first reflective electrode RE1 through a first via VIA1 penetrating the planarization layer PLNL. The second anode electrode AE2 may be connected to the second reflective electrode RE2 through a second via VIA2 penetrating the planarization layer PLNL. The third anode electrode AE3 may be connected to the third reflective electrode RE3 through a third via VIA3 penetrating the planarization layer PLNL.

In some embodiments, the first to third anode electrodes AE1 to AE3 may include at least one of transparent conductive materials, such as indium tin oxide (ITO), indium zinc oxide (IZO), zinc oxide (ZnOx), indium gallium zinc oxide (IGZO), and indium tin zinc oxide (ITZO). However, the materials of the first to third anode electrodes AE1 to AE3 are not limited thereto. For example, the first to third anode electrodes AE1 to AE3 may include titanium nitride.

In some embodiments, insulating layers may be further provided to adjust the height of one or more of the first to third anode electrodes AE1 to AE3. The insulating layers may be disposed between one or more of the first to third anode electrodes AE1 to AE3 and the reflective electrodes. In such an embodiment, the planarization layer PLNL and/or buffer pattern BFP may be omitted. For example, the first to third sub-pixels SP1 to SP3 may correspond to red, green, and blue, respectively. In addition, the distance between the first anode electrode AE1 and the cathode electrode CE may be shorter than the distance between the second anode electrode AE2 and the cathode electrode CE, and the distance between the second anode electrode AE2 and the cathode electrode CE may be shorter than the distance between the third anode electrode AE3 and the cathode electrode CE.

The pixel defining layer PDL may be disposed on portions of the first to third anode electrodes AE1 to AE3 and the planarization layer PLNL. The pixel defining layer PDL may include the openings OP exposing portions of the first to third anode electrodes AE1 to AE3. The openings OP in the pixel defining layer PDL may define emission areas of the first to third sub-pixels SP1 to SP3. As described above, the pixel defining layer PDL may be disposed in the non-emission area NEA shown in FIG. 6 and define the first to third emission areas EMA1 to EMA3 of FIG. 6.

According to an embodiment, the pixel defining layer PDL may include a plurality of inorganic insulating layers. Each of the plurality of inorganic insulating layers may include at least one of silicon oxide (SiOx) and silicon nitride (SiNₓ). For example, the pixel defining layer PDL may include first to third inorganic insulating layers sequentially stacked on each other, and each of the first to third inorganic insulating layers may include silicon nitride, silicon oxide, and silicon nitride. However, embodiments are not limited thereto. The first to third inorganic insulating layers may have a step-shaped cross section in an area adjacent to the opening OP, but the present disclosure is not limited thereto.

A separation layer SPR may be provided in a boundary area BDA between neighboring sub-pixels. As an example, the separation layer SPR may be provided in each boundary area between the sub-pixels SP shown in FIG. 4. The separation layer SPR may be provided on the pixel defining layer PDL.

The separation layer SPR may cause a discontinuity to be formed within the light emitting structure EMS at the boundary area BDA. For example, the light emitting structure EMS may be separated (e.g., broken) or bent in the boundary area BDA by the separation layer SPR.

As shown in FIG. 8, the separation layer SPR may have a void VD. The separation layer SPR may have an opening that partially exposes (or opens) the void VD.

Some or all of a plurality of layers included in the light emitting structure EMS may be separated or bent in the boundary area BDA by the opening in the separation layer SPR or the void VD exposed by the opening in the separation layer SPR. Some or all of the plurality of layers included in the light emitting structure EMS may be separated or bent on the opening of the separation layer SPR or on the void VD exposed by the opening in the separation layer SPR. For example, at least one charge generation layer included in the light emitting structure EMS may be separated in the boundary area BDA by the opening in the separation layer SPR or the void VD exposed by the opening in the separation layer SPR.

The separation layer SPR may include various types of inorganic materials, such as silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ), but the present disclosure is not limited thereto.

A conductive layer CL may be further disposed on the pixel defining layer PDL. The conductive layer CL may be disposed in the void VD in the separation layer SPR. As an example, the separation layer SPR may at least partially surround the conductive layer CL. The conductive layer CL may include titanium (Ti), but the present disclosure is not limited thereto.

As shown in FIGS. 9 to 11, the conductive layer CL may be omitted depending on embodiment. In such an embodiment, the pixel defining layer PDL may be at least partially exposed by the void VD in the separation layer SPR. The pixel defining layer PDL may have a first area A1 overlapping the void VD in the separation layer SPR, and a second area A2 excluding (or other than) the first area A1. As shown in FIG. 10, a thickness H1 of the first area A1 of the pixel defining layer PDL may be a same as a thickness H2 of the second area A2. According to an embodiment, as shown in FIG. 11, the thickness H1 of the first area A1 of the pixel defining layer PDL may be smaller than the thickness H2 of the second area A2, but the present disclosure is not limited thereto.

The light emitting structure EMS may be disposed on the anode electrodes AE and the separation layer SPR. The light emitting structure EMS may be disposed on the anode electrodes AE exposed by the openings OP in the pixel defining layer PDL. The light emitting structure EMS may fill the openings OP in the pixel defining layer PDL and may be disposed entirely across the first to third sub-pixels SP1 to SP3.

As described above, the light emitting structure EMS may be at least partially separated or bent in the boundary area BDA by the separation layer SPR. As an example, the light emitting structure EMS may be separated in the boundary area BDA by the opening of the separation layer SPR or the void VD exposed by the opening in the separation layer SPR. The light emitting structure EMS may be at least partially separated or bent on the opening in the separation layer SPR or on the void VD exposed by the opening in the separation layer SPR. Accordingly, when the display panel DP operates, current flowing from each of the first to third sub-pixels SP1 to SP3 to neighboring sub-pixels through the layers included in the light emitting structure EMS may be reduced. Accordingly, the first to third light emitting elements LD1 to LD3 may operate with relatively high reliability.

The cathode electrode CE may be disposed on the light emitting structure EMS. The cathode electrode CE may be commonly provided to the first to third sub-pixels SP1 to SP3. The cathode electrode CE may act as a half mirror that partially transmits and partially reflects the light emitted from the light emitting structure EMS.

The cathode electrode CE may cover the opening in the separation layer SPR or the void VD exposed by the opening in the separation layer SPR. The cathode electrode CE may be connected in the boundary area BDA and commonly provided to the first to third sub-pixels SP1 to SP3. In the boundary area BDA, the cathode electrode CE may be connected on (or over) the opening of the separation layer SPR or on (or over) the void VD exposed by the opening in the separation layer SPR.

The first anode electrode AE1, a portion of the light emitting structure EMS overlapping the first anode electrode AE1, and a portion of the cathode electrode CE overlapping the first anode electrode AE1 may constitute the first light emitting element LD1. The second anode electrode AE2, a portion of the light emitting structure EMS overlapping the second anode electrode AE2, and a portion of the cathode electrode CE overlapping the second anode electrode AE2 may constitute the second light emitting element LD2. The third anode electrode AE3, a portion of the light emitting structure EMS overlapping the third anode electrode AE3, and a portion of the cathode electrode CE overlapping the third anode electrode AE3 may constitute the third light emitting element LD3.

The encapsulation layer TFE may be disposed on the cathode electrode CE. The encapsulation layer TFE may prevent oxygen and/or moisture from penetrating into the light emitting element layer LDL.

The optical functional layer OFL may be disposed on the encapsulation layer TFE. In some embodiments, the optical functional layer OFL may be attached to the encapsulation layer TFE through an adhesive layer APL. For example, the optical functional layer OFL may be manufactured separately and attached to the encapsulation layer TFE through the adhesive layer APL. The adhesive layer APL may also protect lower layers including the encapsulation layer TFE.

The optical functional layer OFL may include a color filter layer CFL and a lens array LA. The color filter layer CFL may include first to third color filters CF1 to CF3 corresponding to the first to third sub-pixels SP1 to SP3. The first to third color filters CF1 to CF3 may transmit light of different wavelength ranges. For example, the first to third color filters CF1 to CF3 may transmit red light, green light, and blue light, respectively.

In some embodiments, the first to third color filters CF1 to CF3 may partially overlap each other in the boundary area BDA. In other embodiments, the first to third color filters CF1 to CF3 may be spaced apart from each other, and a black matrix may be provided between the first to third color filters CF1 to CF3.

The lens array LA may be disposed on the color filter layer CFL. The lens array LA may include first to third lenses LS1 to LS3 corresponding to the first to third sub-pixels SP1 to SP3. The first to third lenses LS1 to LS3 may improve light output efficiency by outputting light emitted from the first to third light emitting elements LD1 to LD3 along an intended path.

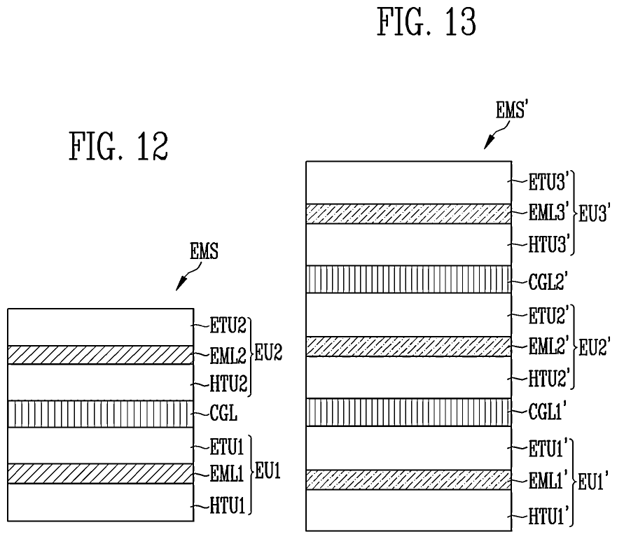

FIG. 12 is a cross-sectional view of a light emitting structure included in one of first to third light emitting elements shown in FIG. 7.

Referring to FIG. 12, the light emitting structure EMS may have a tandem structure in which first and second light emitting units EU1 and EU2 are stacked. The light emitting structure EMS may be configured substantially the same in each of the first to third light emitting elements LD1 to LD3 shown in FIG. 7.

Each of the first and second light emitting units EU1 and EU2 may include at least one light emitting layer that generates light according to an applied current. The first light emitting unit EU1 may include a first light emitting layer EML1, a first electron transport unit ETU1, and a first hole transport unit HTU1. The first light emitting layer EML1 may be disposed between the first electron transport unit ETU1 and the first hole transport unit HTU1. The second light emitting unit EU2 may include a second light emitting layer EML2, a second electron transport unit ETU2, and a second hole transport unit HTU2. The second light emitting layer EML2 may be disposed between the second electron transport unit ETU2 and the second hole transport unit HTU2.

Each of the first and second hole transport units HTU1 and HTU2 may include at least one of a hole injection layer and a hole transport layer and may further include a hole buffer layer, an electron blocking layer, and the like. The first and second hole transport units HTU1 and HTU2 may have the same configuration or different configurations.

Each of the first and second electron transport units ETU1 and ETU2 may include at least one of an electron injection layer and an electron transport layer and may further include an electron buffer layer, a hole blocking layer, and the like. The first and second electron transport units ETU1 and ETU2 may have the same configuration or different configurations.

A connection layer, which may be provided in the form of a charge generation layer CGL, may be disposed between the first light emitting unit EU1 and the second light emitting unit EU2 to connect them to each other. In some embodiments, the charge generation layer CGL may have a stacked structure including a p-type dopant layer and an n-type dopant layer. For example, the p-type dopant layer may include a p-type dopant, such as HAT-CN, TCNQ, NDP-9, and the like, and the n-type dopant layer may include an alkali metal, an alkaline earth metal, a lanthanide-based metal, or a combination thereof. However, embodiments are not limited thereto.

In some embodiments, the first light emitting layer EML1 and the second light emitting layer EML2 may generate light of different colors. Light emitted from each of the first and second light emitting layers EML1 and EML2 may be mixed and visually recognized as white light. For example, the first light emitting layer EML1 may generate blue light, and the second light emitting layer EML2 may generate yellow light. In some embodiments, the second light emitting layer EML2 may include a structure in which a first sub-light emitting layer configured to generate red light and a second sub-light emitting layer configured to generate green light are stacked. Red light and green light may be mixed to provide yellow light. In such an embodiment, an intermediate layer configured to transport holes and/or block the transport of electrons may be further disposed between the first and second sub-light emitting layers.

In other embodiments, the first light emitting layer EML1 and the second light emitting layer EML2 may generate light of a same color.

The light emitting structure EMS may be formed through a method such as vacuum deposition, inkjet printing, or the like, but embodiments are not limited thereto.

FIG. 13 is a cross-sectional view of the light emitting structure included in one of the first to third light emitting elements shown in FIG. 7 according to another embodiment.

Referring to FIG. 13, a light emitting structure EMS′ may have a tandem structure in which first to third light emitting units EU1′ to EU3′ are stacked. The light emitting structure EMS′ may be configured substantially the same in each of the first to third light emitting elements LD1 to LD3 shown in FIG. 7.

Each of the first to third light emitting units EU1′ to EU3′ may include a light emitting layer that generates light according to an applied current. The first light emitting unit EU1′ may include a first light emitting layer EML1′, a first electron transport unit ETU1′, and a first hole transport unit HTU1′. The first light emitting layer EML1′ may be disposed between the first electron transport unit ETU1′ and the first hole transport unit HTU1′. The second light emitting unit EU2′ may include a second light emitting layer EML2′, a second electron transport unit ETU2′, and a second hole transport unit HTU2′. The second light emitting layer EML2′ may be disposed between the second electron transport unit ETU2′ and the second hole transport unit HTU2′. The third light emitting unit EU3′ may include a third light emitting layer EML3′, a third electron transport unit ETU3′, and a third hole transport unit HTU3′. The third light emitting layer EML3′ may be disposed between the third electron transport unit ETU3′ and the third hole transport unit HTU3′.

Each of the first to third hole transport units HTU1′ to HTU3′ may include at least one of a hole injection layer and a hole transport layer and may further include a hole buffer layer, an electron blocking layer, and the like. The first to third hole transport units HTU1′ to HTU3′ may have the same configuration or different configurations.

Each of the first to third electron transport units ETU1′ to ETU3′ may include at least one of an electron injection layer and an electron transport layer and may further include an electron buffer layer, a hole blocking layer, and the like. The first to third electron transport units ETU1′ to ETU3′ may have the same configuration or different configurations.

A first charge generation layer CGL1′ may be disposed between the first light emitting unit EU1′ and the second light emitting unit EU2′. A second charge generation layer CGL2′ may be disposed between the second light emitting unit EU2′ and the third light emitting unit EU3′.

In some embodiments, the first to third light emitting layers EML1′ to EML3′ may generate light of different colors. Light emitted from each of the first to third light emitting layers EML1′ to EML3′ may be mixed and visually recognized as white light. For example, the first light emitting layer EML1′ may generate blue light, the second light emitting layer EML2′ may generate green light, and the third light emitting layer EML3′ may generate red light.

In other embodiments, two or more of the first to third light emitting layers EML1′ to EML3′ may generate light of a same color.

Different from the embodiments shown in FIGS. 12 and 13, the light emitting structure EMS shown in FIG. 7 may include one light emitting unit in each of the first to third light emitting elements LD1 to LD3. In such an embodiment, the light emitting unit included in each of the first to third light emitting elements LD1 to LD3 may be configured to emit light of different colors. For example, the light emitting unit of the first light emitting element LD1 may emit red light, the light emitting unit of the second light emitting element LD2 may emit green light, and the light emitting unit of the third light emitting element LD3 may emit blue light. In such an embodiment, different from the embodiment shown in FIG. 7, the light emitting units of the first to third sub-pixels SP1 to SP3 may be separated from each other, and each of them may be disposed within the opening OP in the pixel defining layer PDL. In such an embodiment, at least some of the color filters CF1 to CF3 may be omitted.

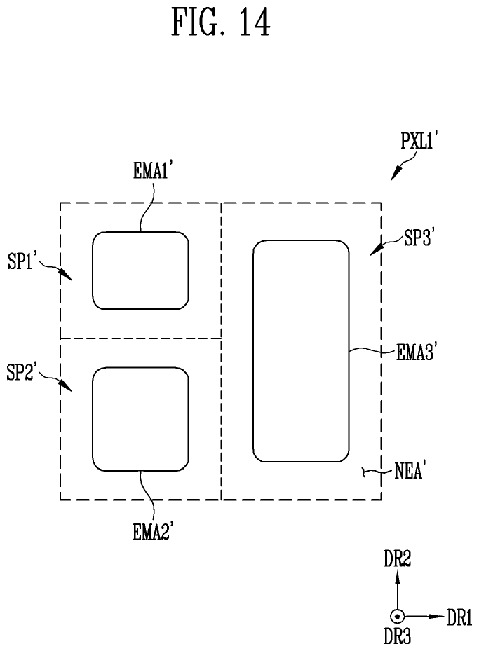

FIG. 14 is a plan view illustrating one of the pixels shown in FIG. 5 according to another embodiment.

Referring to FIG. 14, a first pixel PXL1′ may include first to third sub-pixels SP1′ to SP3′.

The first sub-pixel SP1′ may have a first emission area EMA1′ and a non-emission area NEA' around the first emission area EMA1′. The second sub-pixel SP2′ may have a second emission area EMA2′ and a non-emission area NEA′ around the second emission area EMA2′. The third sub-pixel SP3′ may have a third emission area EMA3′ and a non-emission area NEA′ around the third emission area EMA3′.

The first sub-pixel SP1′ and the second sub-pixel SP2′ may be arranged in the second direction DR2. The third sub-pixel SP3′ may be arranged in the first direction DR1 with respect to each of the first and second sub-pixels SP1′ and SP2′.

The second sub-pixel SP2′ may have a larger area than the first sub-pixel SP1′, and the third sub-pixel SP3′ may have a larger area than the second sub-pixel SP2′. Accordingly, the second emission area EMA2′ may have a larger area than the first emission area EMA1′, and the third emission area EMA3′ may have a larger area than the second emission area EMA2′. However, embodiments are not limited thereto. For example, the first and second sub-pixels SP1′ and SP2′ may have substantially the same area, and the third sub-pixel SP3′ may have a larger area than each of the first and second sub-pixels SP1′ and SP2′. As such, areas of the first to third sub-pixels SP1′ to SP3′ may vary depending on embodiments.

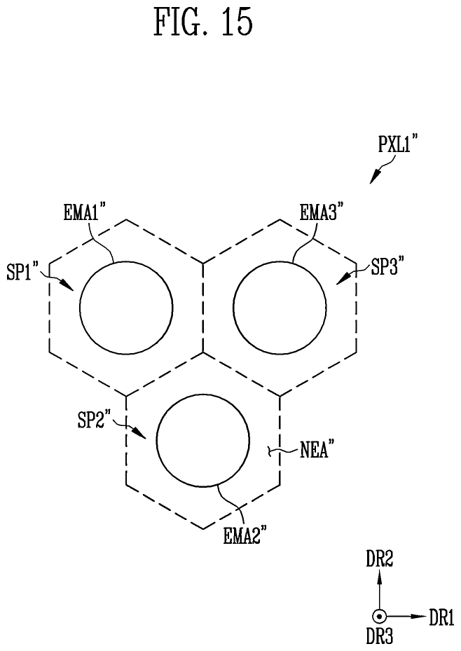

FIG. 15 is a plan view illustrating one of the pixels shown in FIG. 5 according to another embodiment.

Referring to FIG. 15, a first sub-pixel SP1″ may have a first emission area EMA1″ and a non-emission area NEA″ around the first emission area EMA1″. A second sub-pixel SP2″ may have a second emission area EMA2″ and a non-emission area NEA″ around the second emission area EMA2″. A third sub-pixel SP3″ may have a third emission area EMA3″ and a non-emission area NEA″ around the third emission area EMA3″.

The first to third sub-pixels SP1″ to SP3″ may have polygonal shapes when viewed in the third direction DR3. For example, the first to third sub-pixels SP1″ to SP3″ may have hexagonal shapes as shown in FIG. 11.

The first to third emission areas EMA1″ to EMA3″ may have circular shapes when viewed in the third direction DR3. However, embodiments are not limited thereto. For example, each of the first to third emission areas EMA1″ to EMA3″ may have a polygonal shape.

The first and third sub-pixels SP1″ and SP3″ may be arranged in the first direction DR1. With respect to the first sub-pixel SP1″, the second sub-pixel SP2″ may be arranged in a direction inclined (or diagonally) by an acute angle with respect to the second direction DR2.

The arrangement of the sub-pixels shown in FIGS. 6, 14, and 15 is only examples, and embodiments are not limited thereto. Each pixel may include two or more sub-pixels, and the sub-pixels may be arranged in various ways. Each of the sub-pixels may have various shapes, and each of the emission areas may also have various shapes.

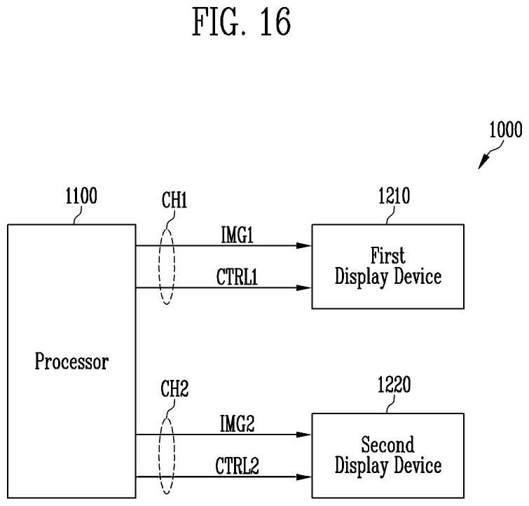

FIG. 16 is a block diagram illustrating an embodiment of a display system.

Referring to FIG. 16, a display system 1000 may include a processor 1100 and one or more display devices 1210 and 1220.

The processor 1100 may perform various tasks and calculations. In some embodiments, the processor 1010 may include an application processor, a graphics processor, a microprocessor, a central processing unit (CPU), or the like. The processor 1100 may be connected to and control other components of the display system 1000 through a bus system.

FIG. 16 shows an embodiment in which the display system 1000 includes first and second display devices 1210 and 1220. The processor 1100 may be connected to the first display device 1210 through a first channel CH1 and may be connected to the second display device 1220 through a second channel CH2.

The processor 1100 may transmit first image data IMG1 and a first control signal CTRL1 to the first display device 1210 through the first channel CH1. The first display device 1210 may display an image based on the first image data IMG1 and the first control signal CTRL1. The first display device 1210 may be configured similarly to the display device 100 described with reference to FIG. 1. In such an embodiment, the first image data IMG1 and the first control signal CTRL1 may be provided as the input image data IMG and the control signal CTRL shown in FIG. 1, respectively.

The processor 1100 may transmit second image data IMG2 and a second control signal CTRL2 to the second display device 1220 through the second channel CH2. The second display device 1220 may display an image based on the second image data IMG2 and the second control signal CTRL2. The second display device 1220 may be configured similarly to the display device 100 described with reference to FIG. 1. In such an embodiment, the second image data IMG2 and the second control signal CTRL2 may be provided as the input image data IMG and the control signal CTRL shown in FIG. 1, respectively.

The display system 1000 may include a computing system that provides an image display function, such as a portable computer, a mobile phone, a smart phone, a tablet personal computer, a smart watch, a watch phone, a portable multimedia player (PMP), a navigation, and an ultra-mobile personal computer (UMPC). The display system 1000 may include at least one of a head-mounted display (HMD) device, a virtual reality (VR) device, a mixed reality (MR) device, and an augmented reality (AR) device.

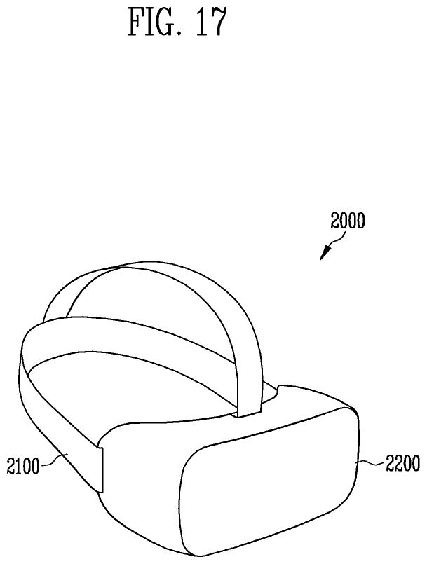

FIG. 17 is a perspective view illustrating an application example of the display system shown in FIG. 16.

Referring to FIG. 17, the display system 1000 shown in FIG. 16 may be applied to a head-mounted display device 2000. The head-mounted display device 2000 may be a wearable electronic device that can be worn on a user's head.

The head-mounted display device 2000 may include a head mounting band 2100 and a display device storage case 2200. The head mounting band 2100 may be connected to the display device storage case 2200. The head mounting band 2100 may include a horizontal band and/or a vertical band for fixing the head-mounted display device 2000 to the user's head. The horizontal band may be configured to surround (e.g., to extend around) the sides of the user's head, and the vertical band may be configured to surround (e.g., to extend around) the top of the user's head. However, embodiments are not limited thereto. For example, the head mounting band 2100 may be implemented in the form of glasses frames, helmets, or the like.

The display device storage case 2200 may accommodate the first and second display devices 1210 and 1220 shown in FIG. 12. The display device storage case 2200 may further accommodate the processor 1100 shown in FIG. 12.

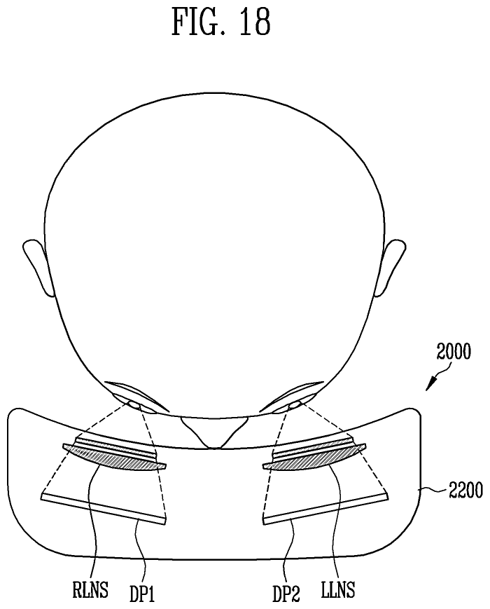

FIG. 18 is a diagram illustrating the head-mounted display device shown in FIG. 17 worn by a user.

Referring to FIG. 18, within the head-mounted display device 2000, a first display panel DP1 of the first display device 1210 and a second display panel DP2 of the second display device 1220 may be disposed. The head-mounted display device 2000 may further include one or more lenses LLNS and RLNS.

Within the display device storage case 2200, a right eye lens RLNS may be disposed between the first display panel DP1 and the user's right eye. Within the display device storage case 2200, a left eye lens LLNS may be disposed between the second display panel DP2 and the user's left eye.

An image output from the first display panel DP1 may be displayed to the user's right eye through the right eye lens RLNS. The right eye lens RLNS may refract light from the first display panel DP1 to be directed toward the user's right eye. The right eye lens RLNS may perform an optical function to adjust the viewing distance between the first display panel DP1 and the user's right eye.

An image output from the second display panel DP2 may be displayed to the user's left eye through the left eye lens LLNS. The left eye lens LLNS may refract light from the second display panel DP2 to be directed toward the user's left eye. The left eye lens LLNS may perform an optical function to adjust the viewing distance between the second display panel DP2 and the user's left eye.

In some embodiments, each of the right eye lens RLNS and the left eye lens LLNS may include an optical lens having a pancake-shaped cross section. In some embodiments, each of the right eye lens RLNS and the left eye lens LLNS may include a multi-channel lens including sub-areas with different optical properties. In such an embodiment, each display panel may output images corresponding to the sub-areas of the multi-channel lens, and the output images may pass through the corresponding sub-areas and may be displayed to the user.

Next, a method of manufacturing the display device according to the above-described embodiments will be described.

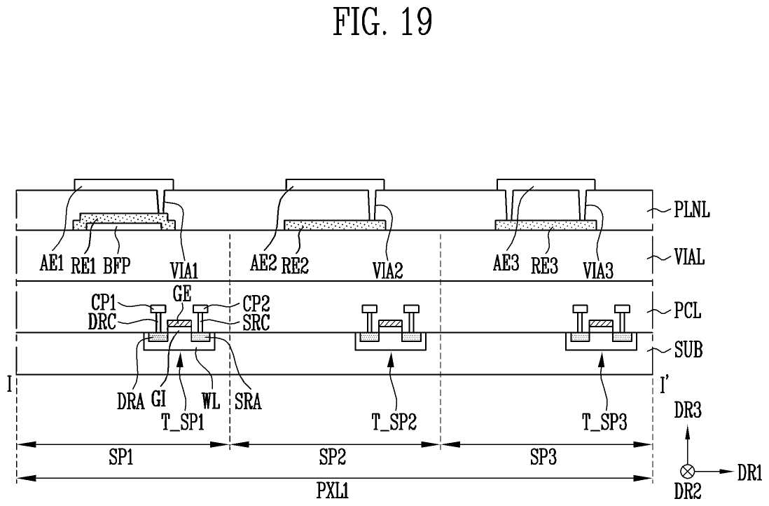

FIGS. 19 to 29 are cross-sectional views illustrating process steps of a method of manufacturing a display device according to an embodiment. FIGS. 19 to 29 are cross-sectional views describing steps of a method of manufacturing the display device shown in FIGS. 7 and 8. For convenience of description, components are briefly shown and some reference numerals are omitted.

Referring to FIG. 19, first, the anode electrode AE may be formed on the substrate SUB. The first to third anode electrodes AE1 to AE3 may be formed on the planarization layer PLNL to overlap the first to third reflective electrodes RE1 to RE3, respectively.

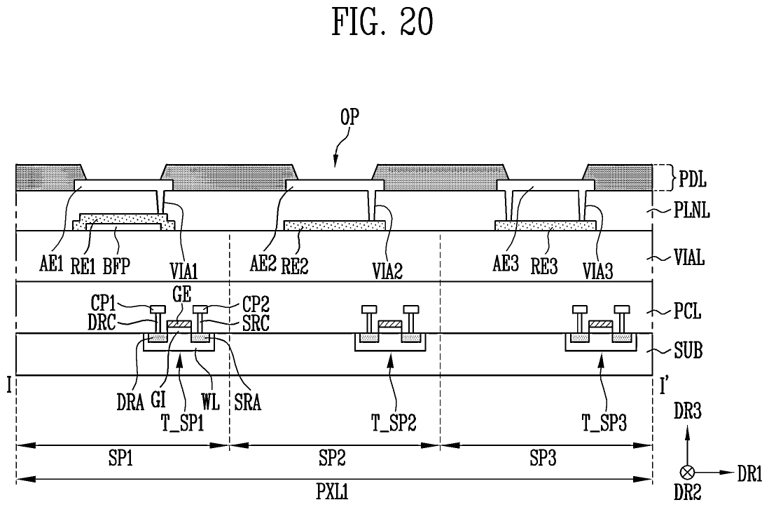

Referring to FIG. 20, next, the pixel defining layer PDL may be formed on the anode electrode AE and the planarization layer PLNL. The pixel defining layer PDL may have (e.g., may be formed, processes, or etched to have) the openings OP exposing portions of the first to third anode electrodes AE1 to AE3.

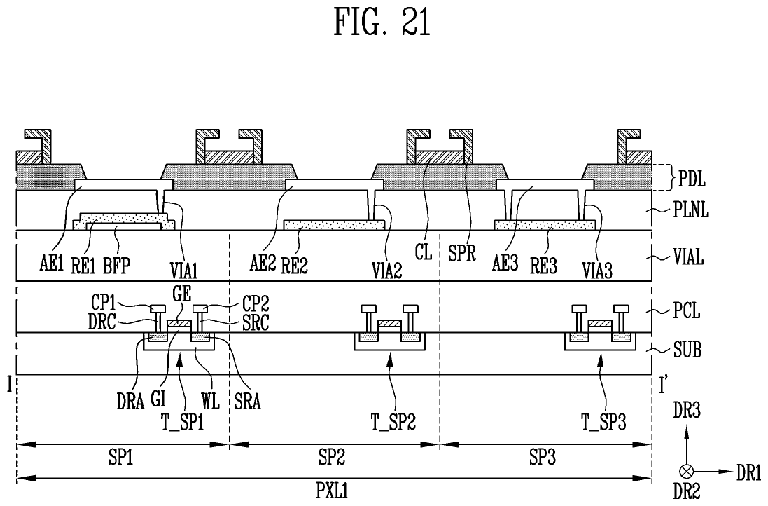

Referring to FIG. 21, the conductive layer CL and the separation layer SPR may be formed on the pixel defining layer PDL. The conductive layer CL and the separation layer SPR may be formed in the boundary area BDA described above (see, e.g., FIG. 7).

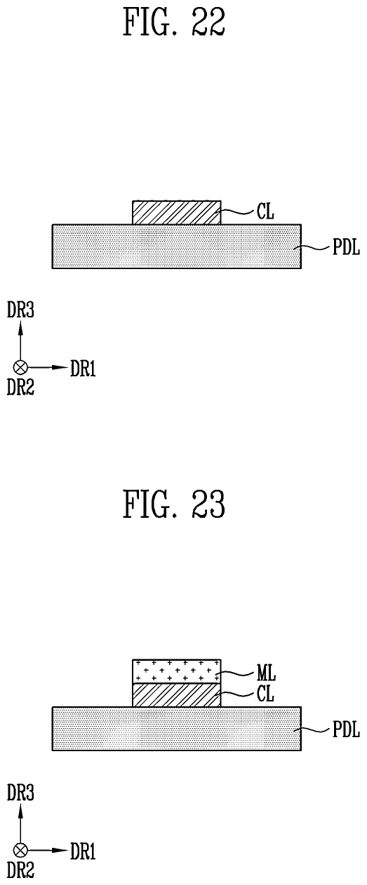

Referring to FIG. 22, first, the conductive layer CL may be formed on the pixel defining layer PDL. The conductive layer CL may be formed simultaneously in the process of forming the pads PD (see FIG. 4), but the present disclosure is not limited thereto.

Referring to FIG. 23, a metal layer ML may be formed on the conductive layer CL. The metal layer ML may be formed directly on the conductive layer CL.

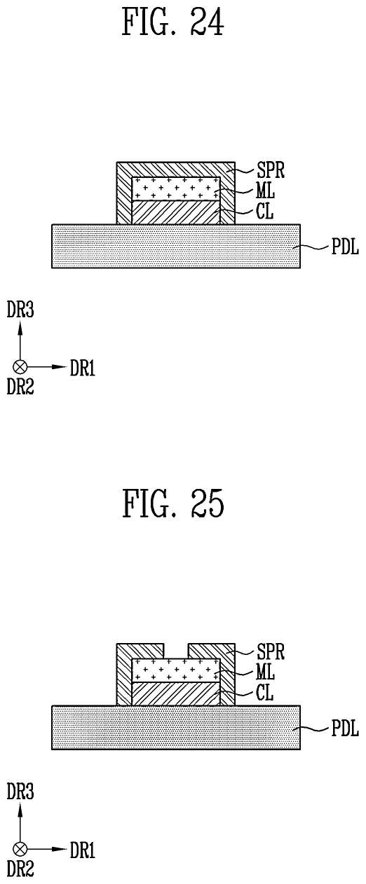

Referring to FIG. 24, the separation layer SPR may be formed on the metal layer ML. The separation layer SPR may be formed of various types of inorganic materials, such as silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ), but the present disclosure is not limited thereto.

Referring to FIG. 25, the separation layer SPR may be partially removed to form the opening. The opening in the separation layer SPR may at least partially expose the metal layer ML.

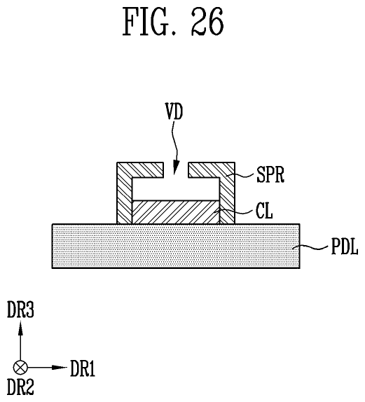

Referring to FIG. 26, the metal layer ML may be etched. The metal layer ML below the separation layer SPR may be removed through the opening in the separation layer SPR.

In the process of etching the metal layer ML, the metal layer ML may be selectively etched due to a difference in a etch ratio between the metal layer ML and the conductive layer CL. For example, in the step of etching the metal layer ML, the pixel defining layer PDL may be covered by the conductive layer CL. For this purpose, the conductive layer CL may be formed of titanium (Ti), and the metal layer ML may be formed of aluminum (Al). However, the materials constituting the metal layer ML and the conductive layer CL are not limited thereto and may be changed in various ways within the range in which the metal layer ML can be selectively etched. As described above, when the metal layer ML disposed below the separation layer SPR is removed, the void VD may be formed between the pixel defining layer PDL and the separation layer SPR. The conductive layer CL may be formed in the void VD and at least partially surrounded by the separation layer SPR.

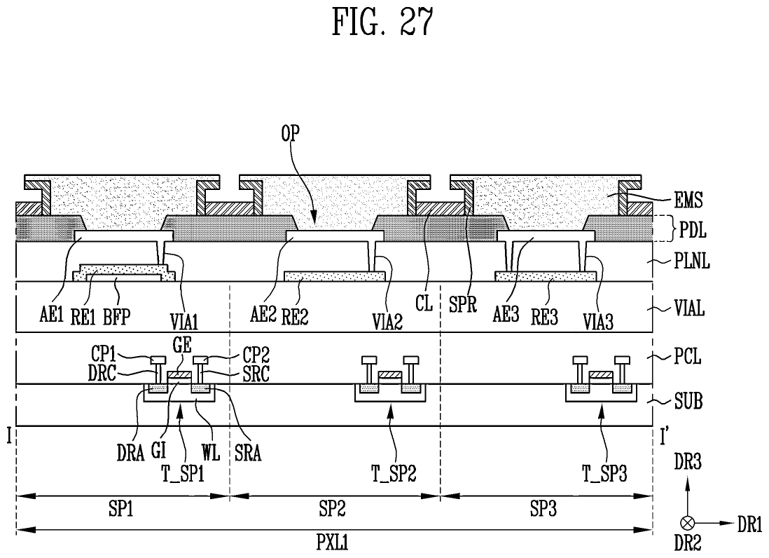

Referring to FIG. 27, the light emitting structure EMS may be formed on the anode electrode AE and the separation layer SPR. Some or all of the plurality of layers included in the light emitting structure EMS may be separated or bent in the boundary area BDA (see, e.g., FIG. 7) by the opening in the separation layer SPR or the void VD exposed by the opening in the separation layer SPR. Some or all of the plurality of layers included in the light emitting structure EMS may be separated or bent on the opening in the separation layer SPR or on the void VD exposed by the opening in the separation layer SPR.

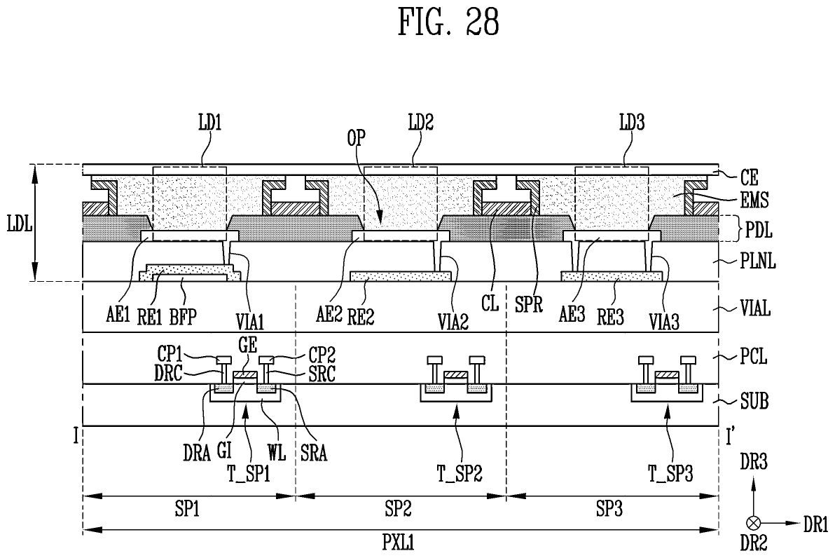

Referring to FIG. 28, the cathode electrode CE may be formed on the light emitting structure EMS. The cathode electrode CE may be commonly provided to the first to third sub-pixels SP1 to SP3. The cathode electrode CE may act as a half mirror that partially transmits and partially reflects the light emitted from the light emitting structure EMS.

The cathode electrode CE may cover the opening in the separation layer SPR or the void VD exposed by the opening in the separation layer SPR. The cathode electrode CE may be connected in the boundary area BDA (see, e.g., FIG. 7) and may be commonly provided to the first to third sub-pixels SP1 to SP3. In the boundary area BDA, the cathode electrode CE may be connected on (e.g., over or may continuously extend over) the opening in the separation layer SPR or on the void VD exposed by the opening in the separation layer SPR.

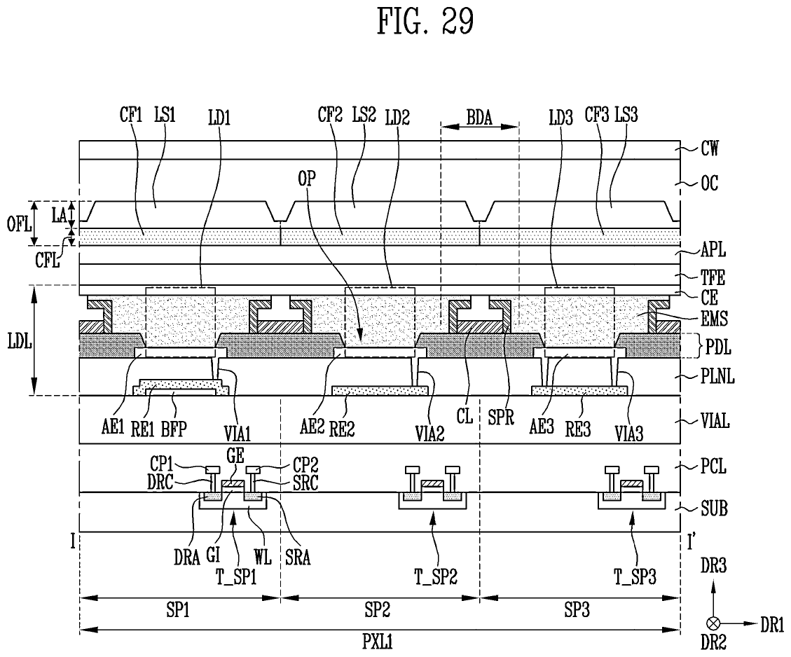

Referring to FIG. 29, the display device shown in FIGS. 7 and 8 may be completed by sequentially forming the encapsulation layer TFE, the optical function layer OFL, the overcoat layer OC, and the cover window CW on the light emitting element layer LDL.

Hereinafter, another embodiment will be described. In the following embodiment, components that are a same as those already described will be referred to by the same reference numerals and overlapping descriptions will be omitted or simplified.

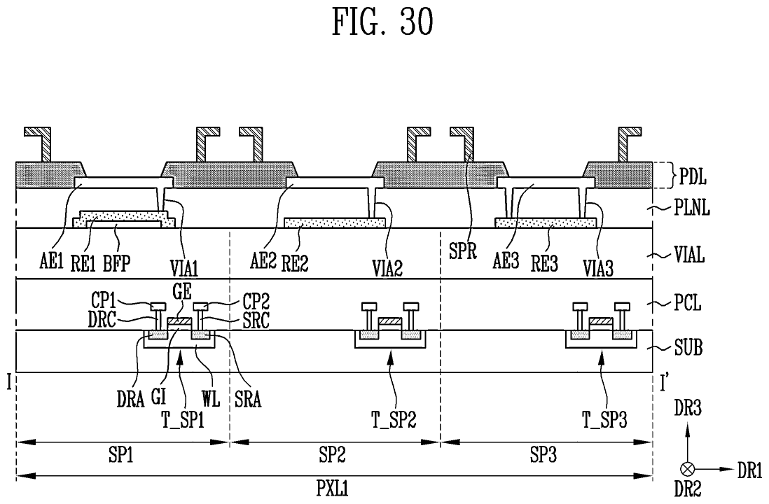

FIGS. 30 to 38 are cross-sectional views illustrating process steps of a method of manufacturing a display device according to an embodiment. FIGS. 30 to 38 are cross-sectional views describing steps of a method of manufacturing the display device shown in FIGS. 9 to 11. For convenience of description, components are briefly shown and some reference numerals are omitted.

Referring to FIG. 30, the separation layer SPR may be formed on the pixel defining layer PDL. Because the starting step to the step of forming the pixel defining layer PDL has been described above with reference to FIGS. 19 and 20, overlapping descriptions will be omitted.

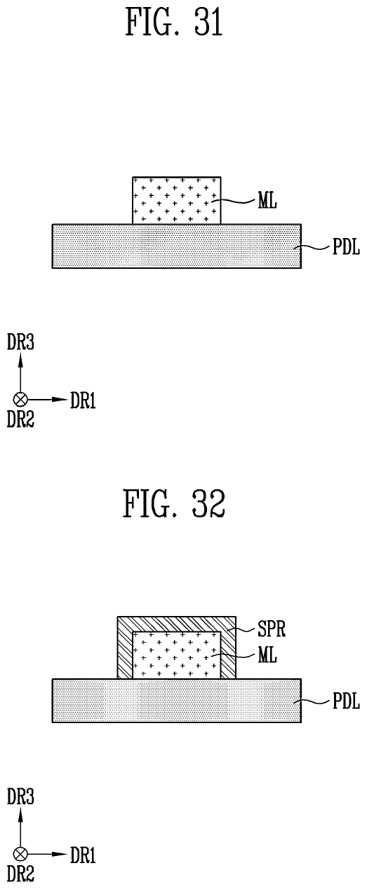

Referring to FIG. 31, first, the metal layer ML may be formed on the pixel defining layer PDL. The metal layer ML may be formed directly on the pixel defining layer PDL.

Referring to FIG. 32, next, the separation layer SPR may be formed on the metal layer ML. The separation layer SPR may be formed of various types of inorganic materials, such as silicon oxide (SiOₓ), silicon nitride _{(SiNx)}, silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ), but the present disclosure is not limited thereto.

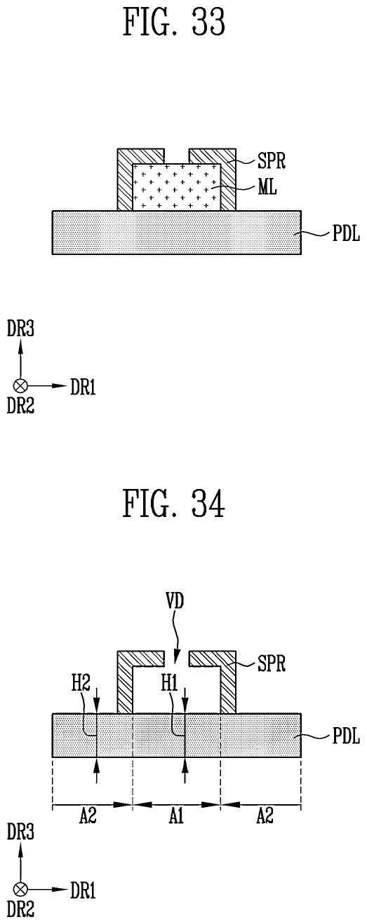

Referring to FIG. 33, the separation layer SPR may be partially removed to form the opening. The opening in the separation layer SPR may at least partially expose the metal layer ML.

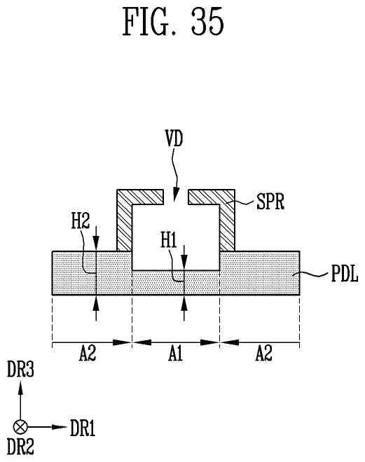

Referring to FIGS. 34 and 35, the metal layer ML may be etched. The metal layer ML below the separation layer SPR may be removed through the opening in the separation layer SPR. When the metal layer ML is removed, the void VD may be formed between the pixel defining layer PDL and the separation layer SPR. The pixel defining layer PDL may have the first area A1 overlapping the void VD in the separation layer SPR and the second area A2 excluding (e.g., other than) the first area A1.

In an embodiment, as shown in FIG. 34, the thickness H1 of the first area A1 of the pixel defining layer PDL may be a same as the thickness H2 of the second area A2. According to an embodiment, as shown in FIG. 35, in the process of etching the metal layer ML, the first area A1 of the pixel defining layer PDL may be at least partially etched. Accordingly, the thickness H1 of the first area A1 of the pixel defining layer PDL may be smaller than the thickness H2 of the second area A2, but the present disclosure is not limited thereto.

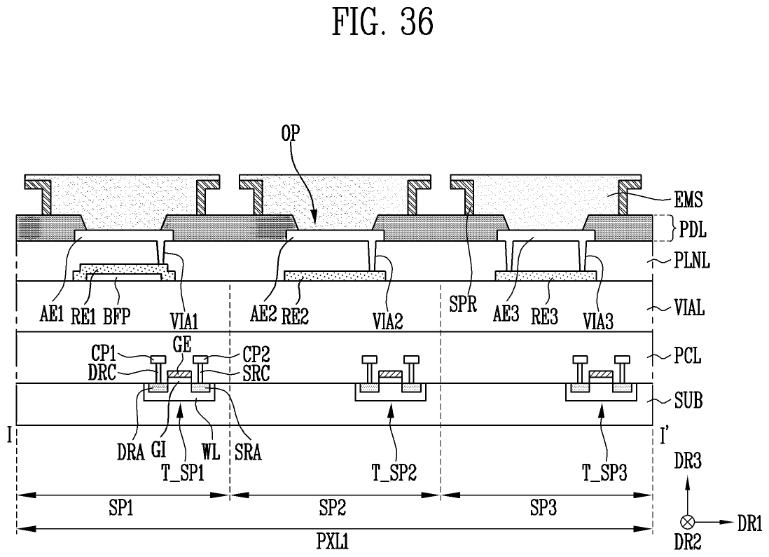

Referring to FIG. 36, the light emitting structure EMS may be formed on the anode electrode AE and the separation layer SPR. Some or all of the plurality of layers included in the light emitting structure EMS may be separated or bent in the boundary area BDA (see, e.g., FIG. 7) by the opening in the separation layer SPR or the void VD exposed by the opening in the separation layer SPR. Some or all of the plurality of layers included in the light emitting structure EMS may be separated or bent on the opening in the separation layer SPR or on the void VD exposed by the opening in the separation layer SPR.

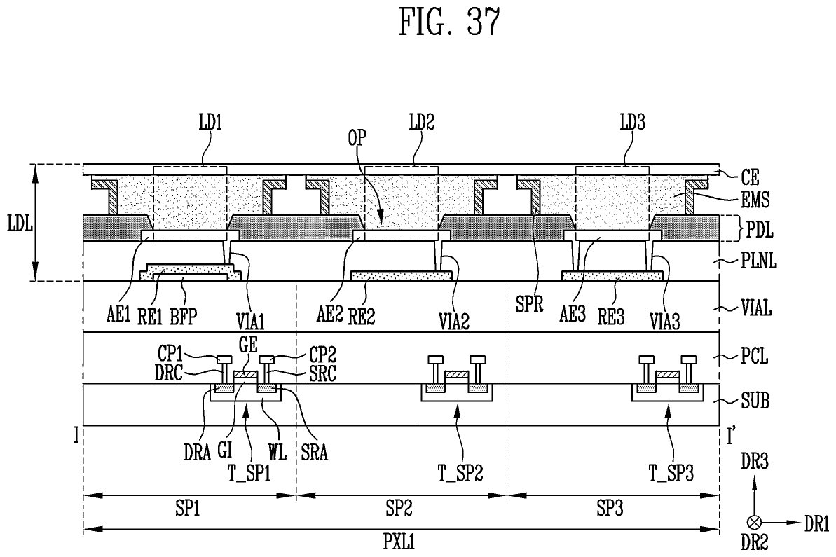

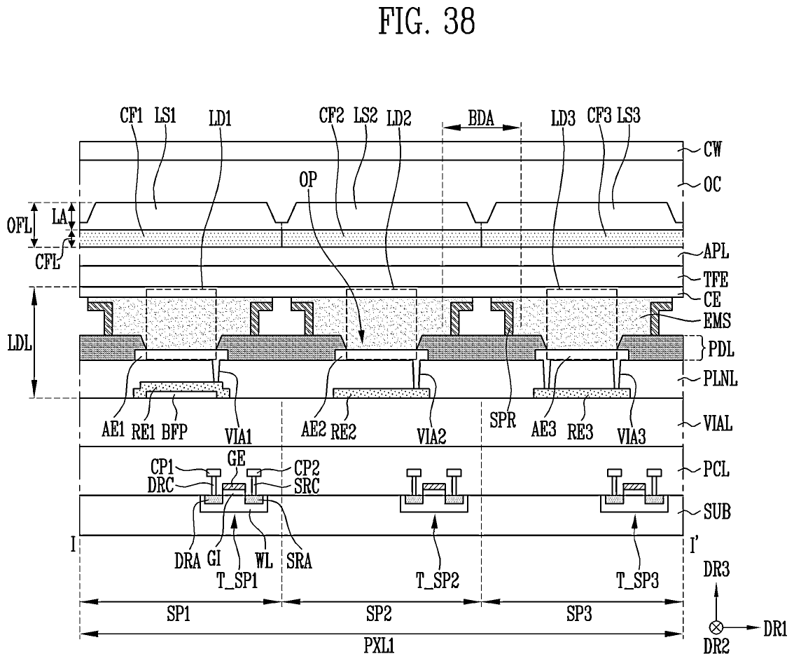

Referring to FIG. 37, the cathode electrode CE may be formed on the light emitting structure EMS. The cathode electrode CE may be commonly provided to the first to third sub-pixels SP1 to SP3. The cathode electrode CE may act as a half mirror that partially transmits and partially reflects the light emitted from the light emitting structure EMS.

The cathode electrode CE may cover the opening in the separation layer SPR or the void VD exposed by the opening in the separation layer SPR. The cathode electrode CE may be connected in (e.g., may continuously extend across) the boundary area BDA (see, e.g., FIG. 7) and may be commonly provided to the first to third sub-pixels SP1 to SP3. In the boundary area BDA, the cathode electrode CE may be connected on (e.g., may extend over) the opening in the separation layer SPR or on the void VD exposed by the opening in the separation layer SPR.

Referring to FIG. 38, the display devices shown in FIGS. 9 to 11 may be completed by sequentially forming the encapsulation layer TFE, the optical function layer OFL, the overcoat layer OC, and the cover window CW on the light emitting element layer LDL.

According to the above-described embodiments, part or all of the light emitting structure may be separated by the separation layer formed in the boundary area between adjacent sub-pixels. Accordingly, current flowing to adjacent sub-pixels can be reduced or minimized.

Aspects and features of the present disclosure are not limited by the above-described aspects, features, and descriptions, and more various other aspects and features are included in the present specification.

Although embodiments, and implementations thereof, have been described herein, other embodiments and modifications may be derived from the foregoing descriptions. Accordingly, the spirit of the present disclosure is not limited to the foregoing embodiments but may also be applied to the claims set forth below and their equivalents.

What is claimed is:

1. A display device comprising:
a first electrode on a substrate;
a pixel defining layer on the first electrode;
a separation layer on the pixel defining layer and having a void and an opening partially exposing the void;
a light emitting unit on the first electrode and the separation layer, the light emitting unit being separated at the opening in the separation layer; and
a second electrode on the light emitting unit and covering the opening in the separation layer.

2. The display device of claim 1, further comprising a conductive layer on the pixel defining layer.

3. The display device of claim 2, wherein the separation layer at least partially surrounds the conductive layer.

4. The display device of claim 2, wherein the conductive layer is in the void.

5. The display device of claim 4, wherein the separation layer comprises an inorganic material.

6. The display device of claim 4, wherein the pixel defining layer has a first area overlapping the void and a second area outside of the first area, and
wherein a thickness of the first area is the same as a thickness of the second area.

7. The display device of claim 4, wherein the pixel defining layer has a first area overlapping the void and a second area outside of the first area, and
wherein a thickness of the first area is smaller than a thickness of the second area.

8. The display device of claim 4, wherein the substrate comprises a first sub-pixel and a second sub-pixel adjacent to each other, and
wherein the separation layer is at a boundary between the first sub-pixel and the second sub-pixel.

9. The display device of claim 8, wherein the light emitting unit of the first sub-pixel and the light emitting unit of the second sub-pixel are separated at the opening in the separation layer.

10. The display device of claim 8, wherein the second electrode of the first sub-pixel and the second electrode of the second sub-pixel are connected over the opening in the separation layer.

11. A method of manufacturing a display device comprising:
forming a first electrode on a substrate;
forming a pixel defining layer on the first electrode;
forming a metal layer on the pixel defining layer;
forming a separation layer on the metal layer;
forming an opening in the separation layer to at least partially expose the metal layer;
etching the metal layer; and
forming a light emitting unit on the first electrode and the separation layer.

12. The method of claim 11, wherein, during the etching of the metal layer, the metal layer is removed to form a void between the pixel defining layer and the separation layer.

13. The method of claim 12, wherein, during the etching of the metal layer, the pixel defining layer is partially etched.

14. The method of claim 12, wherein the light emitting unit is separated at the void.

15. The method of claim 14, further comprising forming a second electrode on the light emitting unit.

16. The method of claim 15, wherein the second electrode covers the opening in the separation layer.

17. The method of claim 14, further comprising forming a conductive layer on the pixel defining layer.

18. The method of claim 17, wherein the metal layer is formed directly on the conductive layer.

19. The method of claim 17, wherein, during the etching of the metal layer, the pixel defining layer is covered by the conductive layer.

20. The method of claim 19, wherein the separation layer at least partially surrounds the conductive layer.
